(19) United States
(12) Patent Application Publication
(10) Pub. No.: US 2026/0007047 A1
(43) Pub. Date: Jan. 1, 2026

(54) DISPLAY DEVICE, ELECTRIC DEVICE AND METHOD OF FABRICATING DISPLAY DEVICE

(71) Applicant: Samsung Display Co., LTD., Yongin-si (KR)

(72) Inventors: Soo Youn KIM, Yongin-si (KR); Hee Jun YANG, Yongin-si (KR); Jeong Seok LEE, Yongin-si (KR); Sang Yeon HWANG, Yongin-si (KR)

(21) Appl. No.: 19/094,853

(22) Filed: Mar. 29, 2025

(30) Foreign Application Priority Data
Jun. 26, 2024 (KR) 10-2024-0083656

(51) Int. Cl. H10K 59/80

(52) U.S. Cl. CPC H10K 59/873

(57) ABSTRACT

A display device includes a substrate, a first electrode disposed on the substrate, a light emitting layer disposed on the first electrode, a second electrode disposed on the light emitting layer and an encapsulation layer disposed on the second electrode, wherein the encapsulation layer includes a first inorganic encapsulation layer disposed on the second electrode, an organic encapsulation layer disposed on the first inorganic encapsulation layer, a second inorganic encapsulation layer disposed on the organic encapsulation layer and the first inorganic encapsulation layer and an intermediate inorganic encapsulation layer disposed between the organic encapsulation layer and the second inorganic encapsulation layer, wherein any one of the surfaces of the intermediate inorganic encapsulation layer opposing each other is in contact with the organic encapsulation layer, and wherein the other of the surfaces of the intermediate inorganic encapsulation layer opposing each other is in contact with the second inorganic encapsulation layer.

This application claims priority to Korean Patent Application No. 10-2024-0083656, filed on Jun. 26, 2024, and all the benefits accruing therefrom under 35 U.S.C. § 119, the content of which in its entirety is herein incorporated by reference.

### BACKGROUND

### 1. Technical Field

The invention relates to a display device, and more particularly, to a display device whose fabricating cost may be reduced, an electronic device, and a method of fabricating the display device.

### 2. Description of the Related Art

Organic light emitting diode displays have self-luminous properties and do not require separate light sources, unlike liquid crystal displays, and may thus have a reduced thickness and weight. In addition, the organic light emitting diode displays have attracted attention as next-generation display devices for televisions (TVs), monitors, and portable electronic devices because they exhibit high-quality characteristics such as low power consumption, high luminance, and a high response speed.

### SUMMARY

Aspects of the invention provide a display device whose fabricating cost may be reduced, an electronic device, and a method of fabricating the display device.

According to an aspect of the invention, there is provided a display device including a substrate, a first electrode disposed on the substrate, a light emitting layer disposed on the first electrode, a second electrode disposed on the light emitting layer and an encapsulation layer disposed on the second electrode, wherein the encapsulation layer includes a first inorganic encapsulation layer disposed on the second electrode, an organic encapsulation layer disposed on the first inorganic encapsulation layer, a second inorganic encapsulation layer disposed on the organic encapsulation layer and the first inorganic encapsulation layer and an intermediate inorganic encapsulation layer disposed between the organic encapsulation layer and the second inorganic encapsulation layer, and wherein any one of the surfaces of the intermediate inorganic encapsulation layer opposing each other is in contact with the organic encapsulation layer, and wherein the other of the surfaces of the intermediate inorganic encapsulation layer opposing each other is in contact with the second inorganic encapsulation layer.

In an embodiment, an end of the organic encapsulation layer may be disposed in a non-display area between a display area of the substrate and a groove of an edge of the substrate.

In an embodiment, the display device may further include a scan driver connected to scan lines disposed in a display area of the substrate and disposed in a non-display area of the substrate, wherein an end of the organic encapsulation layer may be disposed in the non-display area between the display area and the scan driver.

In an embodiment, the intermediate inorganic encapsulation layer may be surrounded by the organic encapsulation layer and the second inorganic encapsulation layer.

In an embodiment, the intermediate inorganic encapsulation layer may include a protrusion portion that does not overlap the organic encapsulation layer.

In an embodiment, the protrusion portion of the intermediate inorganic encapsulation layer may overlap an extension portion of the second inorganic encapsulation layer.

In an embodiment, an extension portion of the first inorganic encapsulation layer and the extension portion of the second inorganic encapsulation layer may be in contact with each other.

In an embodiment, the protrusion portion of the intermediate inorganic encapsulation layer may have a length smaller than or equal to about 20 μm.

In an embodiment, an end of the organic encapsulation layer may have an inclined surface.

In an embodiment, an angle formed by the end of the organic encapsulation layer and a lower surface of the organic encapsulation layer may be an acute angle.

In an embodiment, the angle formed by the end of the organic encapsulation layer and the lower surface of the organic encapsulation layer may be greater than or equal to about 20° and smaller than about 90°.

In an embodiment, an angle formed by the end of the organic encapsulation layer and a lower surface of the organic encapsulation layer may be an obtuse angle.

In an embodiment, the angle formed by the end of the organic encapsulation layer and the lower surface of the organic encapsulation layer may be greater than or equal to about 90° and smaller than or equal to about 120°.

In an embodiment, the display device may further include at least one dam disposed in a dam area of the substrate.

In an embodiment, the display device may further include an organic layer disposed on the second inorganic encapsulation layer.

According to another aspect of the invention, there is provided a display device including a substrate, a first electrode disposed on the substrate, a light emitting layer disposed on the first electrode, a second electrode disposed on the light emitting layer and an encapsulation layer disposed on the second electrode, wherein the encapsulation layer includes a first inorganic encapsulation layer disposed on the second electrode, an organic encapsulation layer disposed on the first inorganic encapsulation layer and a second inorganic encapsulation layer disposed on the organic encapsulation layer and the first inorganic encapsulation layer, wherein the second inorganic encapsulation layer has a greater thickness on the organic encapsulation layer than on the first inorganic encapsulation layer.

In an embodiment, the second inorganic encapsulation layer may include a protrusion portion that does not overlap the organic encapsulation layer.

In an embodiment, the protrusion portion of the second inorganic encapsulation layer may overlap an extension portion of the second inorganic encapsulation layer.

According to still another aspect of the invention, there is provided an electronic device including a display device providing a screen, wherein the display device includes a substrate, a first electrode disposed on the substrate, a light emitting layer disposed on the first electrode, a second electrode disposed on the light emitting layer and an encapsulation layer disposed on the second electrode, wherein the encapsulation layer includes a first inorganic encapsulation layer disposed on the second electrode, an organic encapsulation layer disposed on the first inorganic encapsulation layer, a second inorganic encapsulation layer disposed on the organic encapsulation layer and the first inorganic encapsulation layer and an intermediate inorganic encapsulation layer disposed between the organic encapsulation layer and the second inorganic encapsulation layer, and wherein any one of surfaces of the intermediate inorganic encapsulation layer opposing each other is in contact with the organic encapsulation layer, and wherein the other of the surfaces of the intermediate inorganic encapsulation layer opposing each other is in contact with the second inorganic encapsulation layer.

According to still another aspect of the invention, there is provided an electronic device including a display device providing a screen, wherein the display device includes a substrate, a first electrode disposed on the substrate, a light emitting layer disposed on the first electrode, a second electrode disposed on the light emitting layer and an encapsulation layer disposed on the second electrode, wherein the encapsulation layer includes a first inorganic encapsulation layer disposed on the second electrode, an organic encapsulation layer disposed on the first inorganic encapsulation layer; and a second inorganic encapsulation layer disposed on the organic encapsulation layer and the first inorganic encapsulation layer, and wherein the second inorganic encapsulation layer has a greater thickness on the organic encapsulation layer than on the first inorganic encapsulation layer.

According to still another aspect of the invention, there is provided a method of fabricating a display device, including preparing a substrate on which a first electrode, a light emitting layer, and a second electrode are disposed, forming a first inorganic encapsulation layer on the second electrode, forming an organic layer on the first inorganic encapsulation layer, disposing a mask on the organic layer, forming an intermediate inorganic encapsulation layer on the organic layer through an opening of the mask and forming an organic encapsulation layer between the first inorganic encapsulation layer and the intermediate inorganic encapsulation layer by removing the exposed organic layer using the intermediate inorganic encapsulation layer as a mask.

In an embodiment, the method of fabricating a display device may further include forming a second inorganic encapsulation layer on the organic encapsulation layer and the first inorganic encapsulation layer.

In an embodiment, the organic layer exposed through the intermediate inorganic encapsulation layer may be removed by an ashing method using at least one of plasma, heat, and laser.

A display device, an electronic device, and a method of fabricating the display device according to an embodiment of the invention may provide the following effects. First, a fabricating cost of the display device may be reduced, second, a bezel area of the display device may be reduced, and third, deterioration of touch sensitivity in an edge area of a substrate may be minimized.

The effects of the invention are not limited to the aforementioned effects, and various other effects will become more apparent to one of ordinary skill in the art to which the invention pertains by referencing the detailed description of the invention given below.

### BRIEF DESCRIPTION OF THE DRAWINGS

The above and other aspects and features of the invention will become more apparent by describing in detail exemplary embodiments thereof with reference to the attached drawings, in which:

FIG. 1 is a perspective view illustrating a display device, according to an embodiment;

FIG. 2 is a layout diagram illustrating a display panel, according to an embodiment;

FIG. 3 is a schematic block diagram illustrating the display device, according to an embodiment;

FIG. 4 is an equivalent circuit diagram illustrating a sub-pixel, according to an embodiment;

FIG. 5 is a layout diagram illustrating an example of a display area of FIG. 2 in detail, according to an embodiment;

FIG. 6 is a layout diagram illustrating an example of area A1 of FIG. 2 in detail, according to an embodiment;

FIG. 7 is a layout diagram illustrating an example of area A1 of FIG. 2 in detail, according to an embodiment;

FIG. 8 is a layout diagram illustrating an example of area A1 of FIG. 2 in detail, according to an embodiment;

FIG. 9 is a cross-sectional view illustrating an example of a cross section of the display panel taken along line I1-I1′ of FIG. 5, according to an embodiment;

FIG. 10 is a cross-sectional view illustrating an example of a cross section of the display panel taken along line I2-I2′ of FIGS. 6 to 8, according to an embodiment;

FIG. 11 is an enlarged view of area A2 of FIG. 10, according to an embodiment;

FIG. 12 is a cross-sectional view illustrating an example of a cross section of a display panel taken along line I2-I2′ of FIGS. 6 to 8, according to an embodiment;

FIG. 13 is a cross-sectional view illustrating an example of a cross section of a display panel taken along line I2-I2′ of FIGS. 6 to 8, according to an embodiment;

FIG. 14 is a cross-sectional view illustrating an example of a cross section of a display panel taken along line I2-I2′ of FIGS. 6 to 8, according to an embodiment;

FIG. 15 is a cross-sectional view illustrating an example of a cross section of a display panel taken along line I2-I2′ of FIGS. 6 to 8, according to an embodiment;

FIG. 16 is an enlarged view of area A3 of FIG. 15, according to an embodiment;

FIG. 17 is a cross-sectional view illustrating an example of a cross section of a display panel taken along line I2-I2′ of FIGS. 6 to 8, according to an embodiment;

FIG. 18 is an enlarged view of area A3 of FIG. 17, according to an embodiment;

FIG. 19 is a cross-sectional view illustrating an example of a cross section of a display panel taken along line I2-I2′ of FIGS. 6 to 8, according to an embodiment;

FIG. 20 is an enlarged view of area A5 of FIG. 19, according to an embodiment;

FIG. 21 is a cross-sectional view of an encapsulation layer, according to an embodiment;

FIG. 22 is a cross-sectional view of an encapsulation layer, according to an embodiment;

FIG. 23 is a cross-sectional view illustrating an example of a cross section of a display panel taken along line I2-I2′ of FIGS. 6 to 8, according to an embodiment;

FIG. 24 is a cross-sectional view for describing processes of a method of fabricating the display device, according to an embodiment;

FIG. 25 is a cross-sectional view for describing processes of a method of fabricating the display device, according to an embodiment;

FIG. 26 is a cross-sectional view for describing processes of a method of fabricating the display device, according to an embodiment;

FIG. 27 is a cross-sectional view for describing processes of a method of fabricating the display device, according to an embodiment; and

FIG. 28 is a perspective view illustrating an electronic device to which the display device is applied, according to an embodiment.

FIG. 29 is a block diagram of an electronic device according to one embodiment.

FIGS. 30, 31 and 32 are schematic diagrams of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the invention may be combined partially or totally. As will be clearly appreciated by those skilled in the art, technically various interactions and operations are possible. Various embodiments can be practiced individually or in combination.

Hereinafter, specific exemplary embodiments will be described with reference to the accompanying drawings.

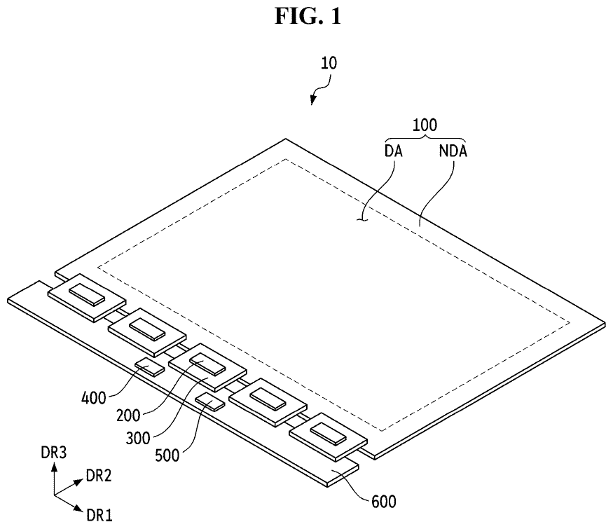

FIG. 1 is a perspective view illustrating a display device, according to an embodiment.

Referring to FIG. 1, a display device 10 is a device that displays a moving image or a still image, and may be used as a display screen of various products such as televisions, laptop computers, monitors, billboards, and the Internet of Things (IoT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

In an embodiment, the display device 10 may be a light emitting display device such as an organic light emitting display device using organic light emitting diodes, a quantum dot light emitting display device including quantum dot light emitting layers, an inorganic light emitting display device including inorganic semiconductors, and a micro light emitting display device using micro or nano light emitting diodes (micro LEDs or nano LEDs). Hereinafter, it will be mainly described that the display device 10 is the organic light emitting display device, but the invention is not limited thereto.

In an embodiment, the display device 10 includes a display panel 100, a plurality of source drivers 200, a plurality of flexible circuit boards 300, a timing controller 400, a power supply unit 500, and a circuit board 600.

The display panel 100 may be formed in a rectangular shape, in a plan view, having long sides in a first direction DR1 and short sides in a second direction DR2 crossing the first direction DR1. A corner where the long side in the first direction DR1 and the short side in the second direction DR2 meet may be rounded with a predetermined curvature or right-angled. A shape of the display panel 100 in a plan view is not limited to the rectangular shape, and may be other polygonal shapes, a circular shape, or an elliptical shape. The display panel 100 may be formed to be flat, but is not limited thereto. As an example, the display panel 100 may include curved surface portions formed at left and right ends thereof and having a constant curvature or a variable curvature. In addition, the display panel 100 may be flexibly formed to be curved, bent, folded, or rolled.

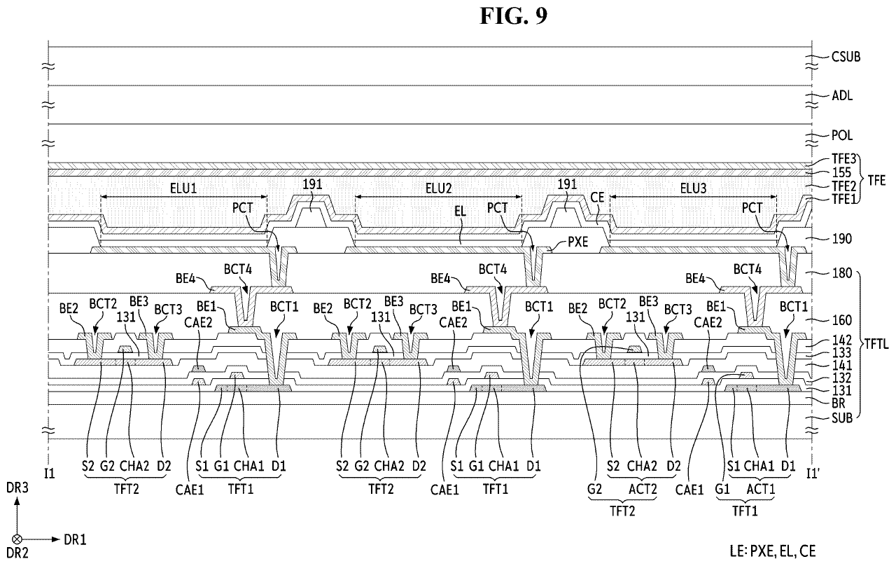

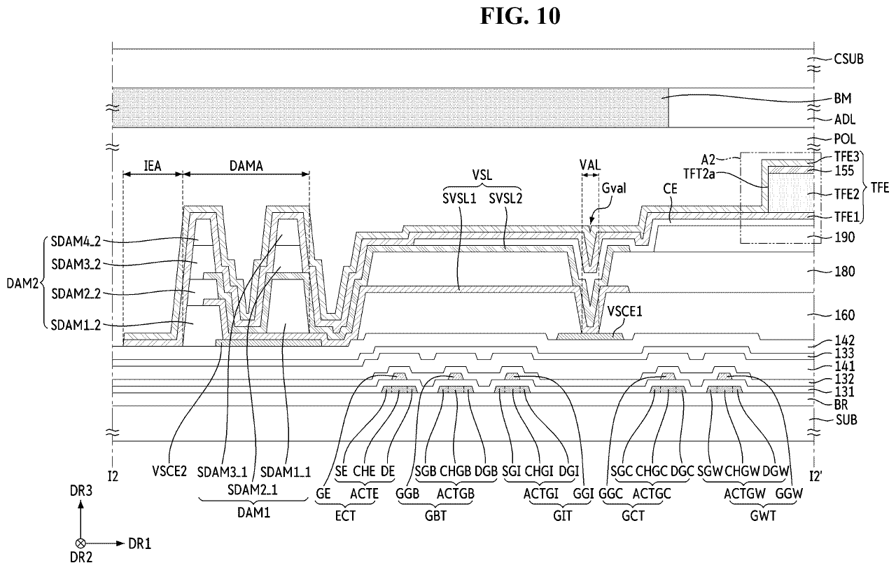

In an embodiment, the display panel 100 may include a display area DA displaying an image and a non-display area NDA disposed around the display area DA. A substrate (e.g., SUB of FIGS. 9 and 10) of the display panel 100 may include a display area DA and a non-display area NDA.

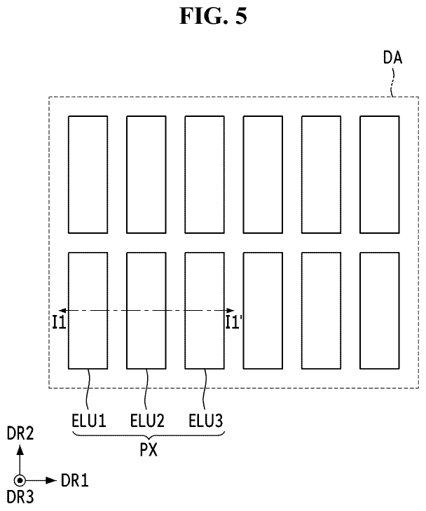

In an embodiment, the display area DA may occupy most of the area of the display panel 100 and may be disposed at the center of the display panel 100. A plurality of pixels PX (see FIG. 5) may be disposed in the display area DA in order to display an image.

The non-display area NDA may be an area that does not display the image and may be an edge area of the display panel 100. The non-display area NDA may be an area disposed outside of the display area DA and may be disposed to surround the display area DA.

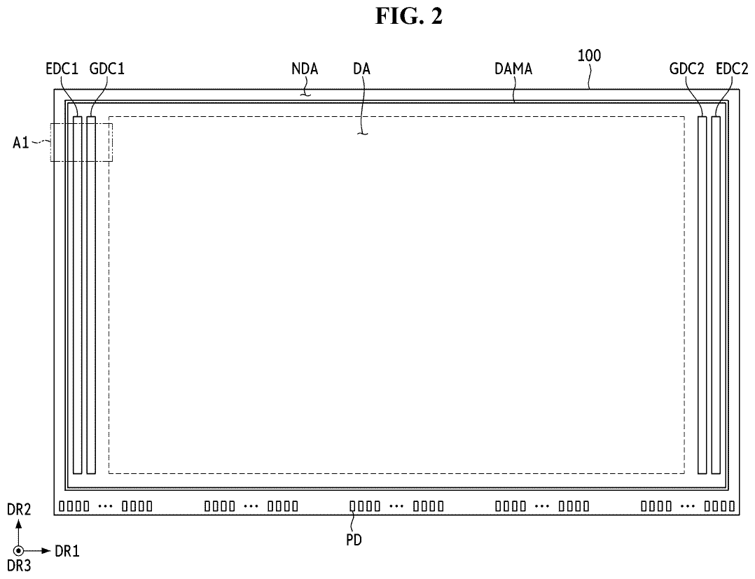

In an embodiment, display pads PD (see FIG. 2) may be disposed in the non-display area NDA in order to be connected to the plurality of flexible circuit boards 300. The display pads PD (see FIG. 2) may be disposed on an edge of one side of the display panel 100.

In an embodiment, each of the source drivers 200 may be formed as an integrated circuit (IC) and attached to the corresponding flexible circuit board 300, but the invention is not limited thereto. In an embodiment, each of the source drivers 200 may be attached onto the display panel 100 in a chip on glass (COG) manner, a chip on plastic (COP) manner, or an ultrasonic bonding manner.

In an embodiment, each of the plurality of flexible circuit boards 300 may be disposed on the display pads PD (see FIG. 2) disposed on the edge of one side of the display panel 100. Each of the plurality of flexible circuit boards 300 may be attached to the display pads PD (see (FIG. 2) using a conductive adhesive member such as an anisotropic conductive film. For this reason, the plurality of flexible circuit boards 300 may be electrically connected to signal lines of the display panel 100. Each of the plurality of flexible circuit boards 300 may be a flexible printed circuit board or a flexible film such as a chip on film.

In an embodiment, the timing controller 400 may generate timing control signals for controlling timings of scan drivers GDC1 and GDC2 (see FIG. 2), emission drivers EDC1 and EDC2 (see FIG. 2), and the source drivers 200. The power supply unit 500 may generate a plurality of source voltages for driving the display panel 100 according to input power input from the outside. Each of the timing controller 400 and the power supply unit 500 may be formed as an integrated circuit (IC) and attached onto the circuit board 600.

In an embodiment, the circuit board 600 may be connected to one side of each of the plurality of flexible circuit boards 300. The circuit board 600 may be a rigid printed circuit board.

FIG. 2 is a layout diagram illustrating a display panel, according to an embodiment.

In an embodiment and referring to FIG. 2, the display panel 100 includes display pads PD, a first scan driver GDC1, a first emission driver EDC1, a second scan driver GDC2, a second emission driver EDC2, and a dam area DAMA.

In an embodiment, the display pads PD may be disposed on the edge of one side of the display panel 100. The display pads PD may be divided into a plurality of groups. When the display device 10 includes five flexible circuit boards 300 as illustrated in FIG. 1, the display pads PD may be divided into five groups. The display pads PD of each of the plurality of groups may correspond to bumps of the corresponding flexible circuit board 300 in a one-to-one manner. Therefore, the display pads PD of each of the plurality of groups may be electrically connected to the corresponding flexible circuit board 300.

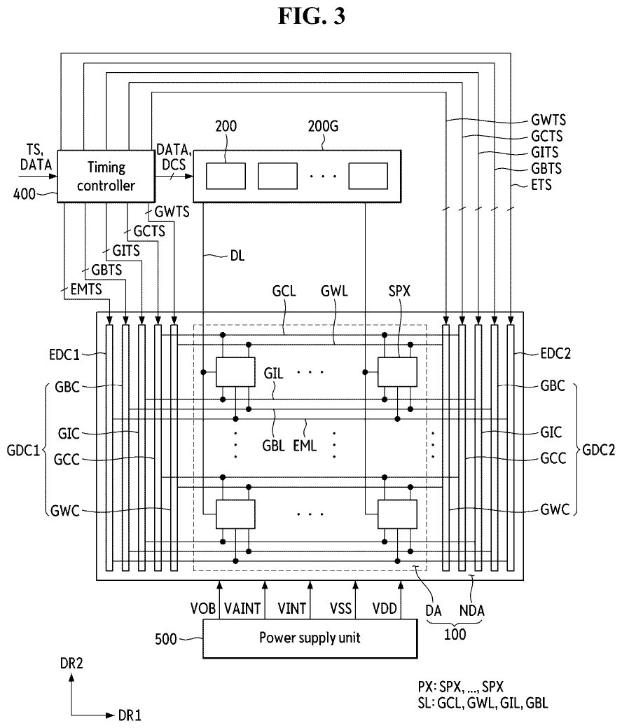

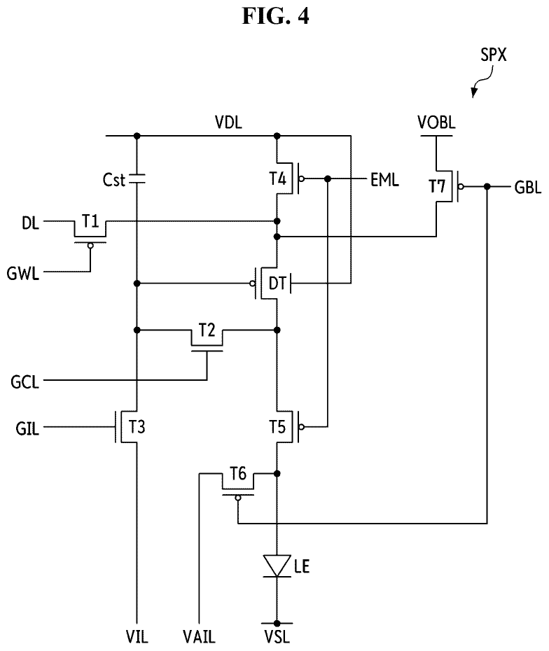

In an embodiment, some of the display pads PD may be electrically connected to data lines DL (see FIG. 3) disposed in the display area DA. Some others of the display pads PD may be electrically connected to the first scan driver GDC1, the second scan driver GDC2, the first emission driver EDC1, and the second emission driver EDC2. Some others of the display pads PD may be connected to a first power line VSL (see FIG. 4) to which a first source voltage is applied.

In an embodiment, the first power line VSL may be disposed to surround at least three sides of the display area DA. For example, the first power line VSL may be disposed to surround the left side, the upper side, and the right side of the display area DA. In another embodiment, the first power line VSL may be disposed to surround the left side, the upper side, the right side, and the lower side of the display area DA.

In an embodiment, the first scan driver GDC1 and the second scan driver GDC2 may be electrically connected to scan lines SL (see FIG. 3) of the display area DA. The first scan driver GDC1 may be disposed in the non-display area NDA on a first side (e.g., the left side) of the display panel 100 and the second scan driver GDC2 may be disposed in the non-display area NDA on a second side (e.g., the right side) of the display panel 100.

In an embodiment, the first emission driver EDC1 and the second emission driver EDC2 may be electrically connected to emission control lines EML (see FIG. 3) of the display area DA. The first emission driver EDC1 may be disposed in the non-display area NDA on the first side (e.g., the left side) of the display panel 100. The second emission driver EDC2 may be disposed in the non-display area NDA on the second side (e.g., the right side) of the display panel 100.

In an embodiment, the first scan driver GDC1 may be disposed between the display area DA and the first emission driver EDC1. The first scan driver GDC1 may be disposed closer to the display area DA than the first emission driver EDC1 is. In addition, the first emission driver EDC1 may be disposed closer to an edge of the first side of the display panel 100 than the first scan driver GDC1 is.

In an embodiment, the second scan driver GDC2 may be disposed between the display area DA and the second emission driver EDC2. The second scan driver GDC2 may be disposed closer to the display area DA than the second emission driver EDC2 is. In addition, the second emission driver EDC2 may be disposed closer to an edge of the second side of the display panel 100 than the second scan driver GDC2 is.

In an embodiment, the dam area DAMA may include at least one dam DM1 and DM2 (see FIG. 10) for preventing an organic encapsulation layer TFE2 (see FIG. 10) from overflowing onto the display pads PD. The dam area DAMA may be disposed to surround the display area DA.

The dam area DAMA may be disposed outside the first emission driver EDC1 and the second emission driver EDC2. The dam area DAMA may be disposed closer to the edge of the first side of the display panel 100 than the first emission driver EDC1 is. In addition, the dam area DAMA may be disposed closer to the edge of the second side of the display panel 100 than the second emission driver EDC2 is.

FIG. 3 is a block diagram illustrating the display device, according to an embodiment.

In an embodiment and referring to FIG. 3, the display area DA includes a plurality of sub-pixels SPX, a plurality of scan lines SL, a plurality of emission control lines EML, and a plurality of data lines DL.

In an embodiment, the plurality of pixels PX may be arranged in a matrix form in the first direction DR1 and the second direction DR2. The plurality of scan lines SL and the plurality of emission control lines EML may extend in the first direction DR1 and may be arranged in the second direction DR2. The plurality of data lines DL may extend in the second direction DR2 and may be arranged in the first direction DR1. The plurality of scan lines SL includes a plurality of write scan lines GWL, a plurality of control scan lines GCL, a plurality of initialization scan lines GIL, and a plurality of bias scan lines GBL.

In an embodiment, each of the plurality of sub-pixels SPX may be connected to any one of the plurality of write scan lines GWL, any one of the plurality of control scan lines GCL, any one of the plurality of initialization scan lines GIL, any one of the plurality of bias scan lines GBL, any one of the plurality of emission control lines EML, and any one of the plurality of data lines DL. Each of the plurality of sub-pixels SPX may receive a data voltage of the data line DL according to a write scan signal of the write scan line GWL and allow a light emitting element to emit light according to the data voltage.

In an embodiment, the non-display area NDA includes the first scan driver GDC1, the second scan driver GDC2, the first emission driver EDC1, and the second emission driver EDC2.

In an embodiment, each of the first scan driver GDC1 and the second scan driver GDC2 may include a write scan driver GWC, a control scan driver GCC, an initialization scan driver GIC, and a bias scan driver GBC. It has been illustrated in FIG. 3 that the write scan driver GWC, the control scan driver GCC, the initialization scan driver GIC, and the bias scan driver GBC are sequentially disposed from the display area DA to the edge of the display panel 100, but an exemplary embodiment of the present disclosure is not limited thereto.

In an embodiment, the write scan driver GWC may receive a write timing signal GWTS from the timing controller 400 and may generate write scan signals according to the write timing signal GWTS and sequentially output the write scan signals to the write scan lines GWL.

In an embodiment, the control scan driver GCC may receive a control timing signal GCTS from the timing controller 400 and may generate control scan signals according to the control timing signal GCTS and sequentially output the control scan signals to the control scan lines GCL.

In an embodiment, the initialization scan driver GIC may receive an initialization timing signal GITS from the timing controller 400 and may generate initialization scan signals according to the initialization timing signal GITS and sequentially output the initialization scan signals to the initialization scan lines GIL.

In an embodiment, the bias scan driver GBC may receive a bias timing signal GBTS from the timing controller 400 and may generate bias scan signals according to the bias timing signal GBTS and sequentially output the bias scan signals to the bias scan lines GBL.

In an embodiment, each of the first emission driver EDC1 and the second emission driver EDC2 may receive an emission timing signal ETS from the timing controller 400. Each of the first emission driver EDC1 and the second emission driver EDC2 may generate emission control signals according to the emission timing signal ETS and sequentially output the emission control signals to the emission control lines EML.

In an embodiment, a data driver 200G includes a plurality of source drivers 200, where each of the plurality of source drivers 200 may receive digital video data DATA and a data timing signal DCS from the timing controller 400. Each of the plurality of source drivers 200 converts the digital video data DATA into analog data voltages according to the data timing signal DCS and outputs the analog data voltages to the data lines DL. In this case, the sub-pixels SPX may be selected by the write scan signals, and the data voltages may be supplied to the selected sub-pixels SPX.

In an embodiment, the timing controller 400 may receive the digital video data DATA and timing signals TS from the outside. The timing controller 400 may generate the write timing signal GWTS, the control timing signal GCTS, the initialization timing signal GITS, the bias timing signal GBTS, and the emission timing signal ETS according to the timing signals TS. The timing controller 400 may output the write timing signal GWTS to the write scan drivers GWC and output the control timing signal GCTS to the control scan drivers GCC. In addition, the timing controller 400 may output the initialization timing signal GITS to the initialization scan drivers GIC and output the bias timing signal GBTS to the bias scan drivers GBC. The timing controller 400 may output the emission timing signal ETS to the first emission driver EDC1 and the second emission driver EDC2. In addition, the timing controller 400 may output the digital video data DATA and the data timing signal DCS to the source drivers 200.

In an embodiment, the power supply unit 500 may generate a plurality of panel driving voltages according to an external source voltage. For example, the power supply unit 500 may generate a first source voltage VSS, a second source voltage VDD, a third source voltage VINT, a fourth source voltage VAINT, and a fifth source voltage VOB and supply the first source voltage VSS, the second source voltage VDD, the third source voltage VINT, the fourth source voltage VAINT, and the fifth source voltage VOB to the display panel 100. The first source voltage VSS may be a low potential voltage, and the second source voltage VDD may be a high potential voltage. The third source voltage VINT may be a first initialization voltage, the fourth source voltage VAINT may be a second initialization voltage, and the fifth source voltage VOB may be a third initialization voltage. The third source voltage VINT, the fourth source voltage VAINT, and the fifth source voltage VOB may be voltages higher than the first source voltage VSS and lower than the second source voltage VDD.

FIG. 4 is an equivalent circuit diagram illustrating a sub-pixel, according to an embodiment.

In an embodiment and referring to FIG. 4, the sub-pixel SPX may be connected to a write scan line GWL, an initialization scan line GIL, a control scan line GCL, a bias scan line GBL, an emission control line EML, and a data line DL.

The sub-pixel SPX, according to an embodiment, includes a driving transistor DT, switch elements, a capacitor Cst, and a light emitting element LE. The switch elements may include first to seventh transistors T1, T2, T3, T4, T5, T6, and T7, respectively.

In an embodiment, the driving transistor DT controls a source-drain current (hereinafter referred to as a “driving current”) according to a data voltage applied to a first gate electrode thereof. A second gate electrode of the driving transistor DT may be connected to a second power line VDL to which the second source voltage VDD (see FIG. 3) is applied.

In an embodiment, the light emitting element LE may be an organic light emitting diode. The light emitting element LE emits light according to the driving current. An amount of light emitted from the light emitting element LE may be proportional to the driving current. A first electrode of the light emitting element LE may be connected to a second electrode of the fifth transistor T5 and a first electrode of the sixth transistor T6. A second electrode of the light emitting element LE may be connected to a first power line VSL to which the first source voltage is applied. The first electrode of the light emitting element LE may be an anode electrode or a pixel electrode, and the second electrode of the light emitting element LE may be a cathode electrode or a common electrode.

In an embodiment, the first transistor T1 is turned on by a write scan signal of a gate-on voltage applied to the write scan line GWL to connect the data line DL to a first electrode of the driving transistor DT. For this reason, the data voltage may be applied to the first electrode of the driving transistor DT during a period in which the first transistor T1 is turned on. A gate electrode of the first transistor T1 may be connected to the write scan line GWL, a first electrode of the first transistor T1 may be connected to the data line DL, and a second electrode of the first transistor T1 may be connected to the first electrode of the driving transistor DT.

In an embodiment, the second transistor T2 is turned on by a control scan signal of a gate-on voltage applied to the control scan line GCL to connect the first gate electrode and a second electrode of the driving transistor DT to each other. During a period in which the second transistor T2 is turned on, the driving transistor DT may operate like a diode. A gate electrode of the second transistor T2 may be connected to the control scan line GCL, a first electrode of the second transistor T2 may be connected to the second electrode of the driving transistor DT, and a second electrode of the second transistor T2 may be connected to the first gate electrode of the driving transistor DT.

In an embodiment, the third transistor T3 is turned on by an initialization scan signal of a gate-on voltage applied to the initialization scan line GIL to connect the first gate electrode of the driving transistor DT to a third power line VIL. During a period in which the third transistor T3 is turned on, the first gate electrode of the driving transistor DT may be initialized to the third source voltage VINT (see FIG. 3) of the third power line VIL. A gate electrode of the third transistor T3 may be connected to the initialization scan line GIL, a first electrode of the third transistor T3 may be connected to the first gate electrode of the driving transistor DT, and a second electrode of the third transistor T3 may be connected to the third power line VIL.

In an embodiment, the fourth transistor T4 is turned on by an emission control signal of a gate-on voltage applied to the emission control line EML to connect the second power line VDL to the first electrode of the driving transistor DT. During a period in which the fourth transistor T4 is turned on, the second source voltage VDD (see FIG. 3) of the second power line VDL may be applied to the first electrode of the driving transistor DT. A gate electrode of the fourth transistor T4 may be connected to the emission control line EML, a first electrode of the fourth transistor T4 may be connected to the second power line VDL, and a second electrode of the fourth transistor T4 may be connected to the first electrode of the driving transistor DT.

In an embodiment, the fifth transistor T5 is turned on by the emission control signal of the gate-on voltage applied to the emission control line EML to connect the second electrode of the driving transistor DT to the first electrode of the light emitting element LE. During a period in which the fifth transistor T5 is turned on, the driving current of the driving transistor DT may be supplied to the light emitting element LE. A gate electrode of the fifth transistor T5 may be connected to the emission control line EML, a first electrode of the fifth transistor T5 may be connected to the second electrode of the driving transistor DT, and the second electrode of the fifth transistor T5 may be connected to the first electrode of the light emitting element LE.

In an embodiment, the sixth transistor T6 is turned on by a bias scan signal of a gate-on voltage applied to the bias scan line GBL to connect the first electrode of the light emitting element LE to a fourth power line VAIL. During a period in which the sixth transistor T6 is turned on, the first electrode of the light emitting element LE may be initialized to the fourth source voltage VAINT (see FIG. 3) of the fourth power line VAIL. A gate electrode of the sixth transistor T6 may be connected to the bias scan line GBL, the first electrode of the sixth transistor T6 may be connected to the first electrode of the light emitting element LE, and a second electrode of the sixth transistor T6 may be connected to the fourth power line VAIL.

In an embodiment, the seventh transistor T7 is turned on by the bias scan signal of the gate-on voltage applied to the bias scan line GBL to connect the first electrode of the driving transistor DT to a fifth power line VOBL. During a period in which the seventh transistor T7 is turned on, the first electrode of the driving transistor DT may be initialized to the fifth source voltage VOB (see FIG. 3) of the fifth power line VOBL. A gate electrode of the seventh transistor T7 may be connected to the bias scan line GBL, a first electrode of the seventh transistor T7 may be connected to the first electrode of the driving transistor DT, and a second electrode of the seventh transistor T7 may be connected to the fifth power line VOBL.

In an embodiment, the capacitor Cst is formed between the first gate electrode of the driving transistor DT and the second power line VDL. One electrode of the capacitor Cst may be connected to the first gate electrode of the driving transistor DT, and the other electrode of the capacitor Cst may be connected to the second power line VDL.

In an embodiment, the driving transistor DT, the first transistor T1, the fourth transistor T4, the fifth transistor T5, the sixth transistor T6, and the seventh transistor T7 may be formed as P-type metal oxide semiconductor field effect transistors (MOSFETs). In this case, an active layer of each of the driving transistor DT, the first transistor T1, the fourth transistor T4, the fifth transistor T5, the sixth transistor T6, and the seventh transistor T7 may be made of polysilicon. In addition, the driving transistor DT, the first transistor T1, the fourth transistor T4, the fifth transistor T5, the sixth transistor T6, and the seventh transistor T7 may be turned on by a signal of a gate low voltage.

In addition, the second transistor T2 and the third transistor T3 may be formed as N-type MOSFETs. In this case, an active layer of each of the second transistor T2 and the third transistor T3 may be made of an oxide semiconductor. In addition, the second transistor T2 and the third transistor T3 may be turned on by a signal of a gate high voltage.

FIG. 5 is a layout diagram illustrating an example of a display area of FIG. 2 in detail, according to an embodiment.

In an embodiment and referring to FIG. 5, a plurality of pixels PX may be arranged in a matrix form, where each of the plurality of pixels PX may include a first light emitting unit ELU1 of a first sub-pixel SPX1, a second light emitting unit ELU2 of a second sub-pixel SPX2, and a third light emitting unit ELU3 of a third sub-pixel SPX3.

In an embodiment, in each of the plurality of pixels PX, the first light emitting unit ELU1, the second light emitting unit ELU2, and the third light emitting unit ELU3 may be arranged in a stripe shape. For example, in each of the plurality of pixels PX, the first light emitting unit ELU1, the second light emitting unit ELU2, and the third light emitting unit ELU3 may be arranged in the first direction DR1.

In an embodiment, the first light emitting unit ELU1 may emit a first light, the second light emitting unit ELU2 may emit a second light, and the third light emitting unit ELU3 may emit a third light. Here, the first light may be light of a blue wavelength band, the second light may be light of a green wavelength band, and the third light may be light of a red wavelength band. For example, the blue wavelength band indicates that a main peak wavelength of the light is included in a wavelength band of approximately 370 nm to approximately 460 nm, the green wavelength band indicates that a main peak wavelength of the light is included in a wavelength band of approximately 480 nm to approximately 560 nm, and the red wavelength band indicates that a main peak wavelength of the light is included in a wavelength band of approximately 600 nm and approximately 750 nm.

An embodiment has been illustrated in FIG. 5 where each of the plurality of pixels PX includes three light emitting units ELU1, ELU2, and ELU3, but the invention is not limited thereto. For example, in an embodiment, each of the plurality of pixels PX may include four light emitting units. In this case, a first light emitting unit may emit first light, a second light emitting unit and a fourth light emitting unit may emit second light, and a third light emitting unit may emit third light. In another embodiment, the first light emitting unit may emit a first light, the second light emitting unit may emit a second light, the third light emitting unit may emit a third light, and the fourth light emitting unit may emit a fourth light, where the fourth light may be a white light. In addition, in each of the plurality of pixels PX, the first light emitting unit, the second light emitting unit, the third light emitting unit, and the fourth light emitting unit may be arranged in a stripe shape or a Pentile® shape.

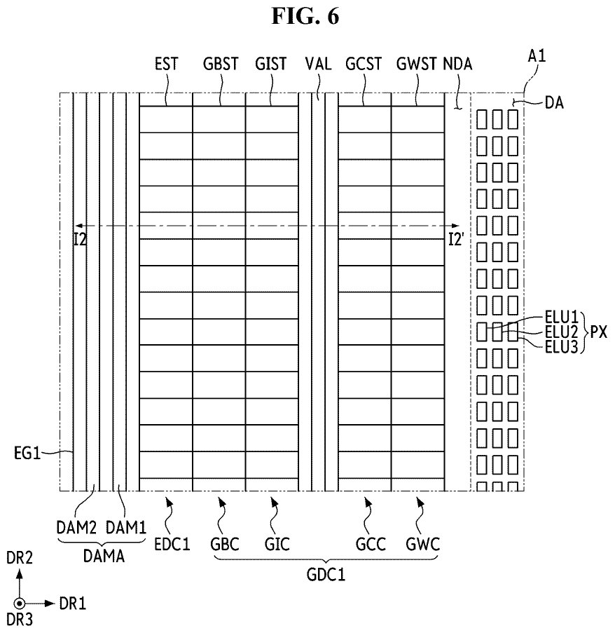

FIGS. 6 to 8 are layout diagrams illustrating an example of area A1 of FIG. 2 in detail, according to an embodiment.

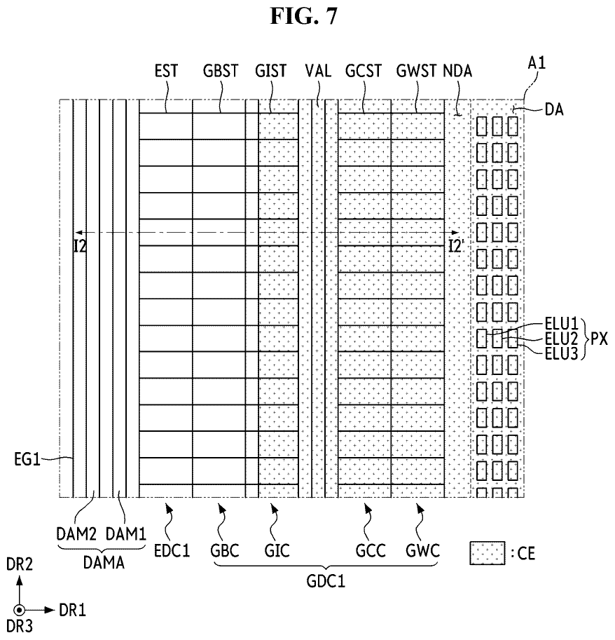

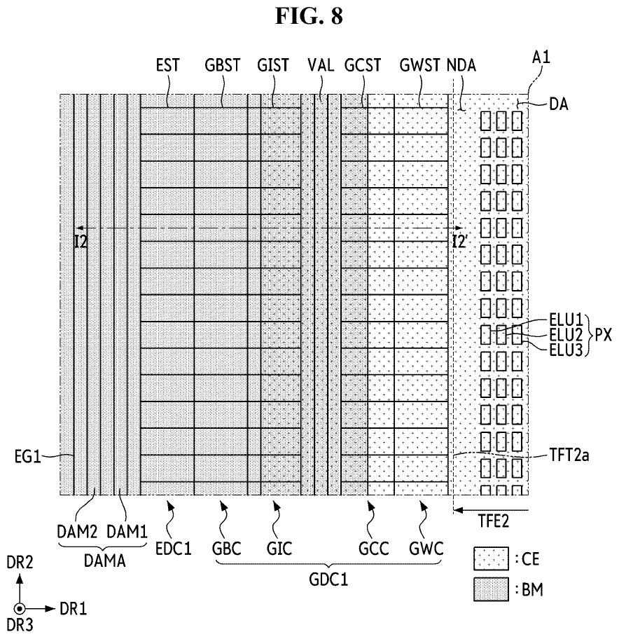

FIGS. 6 to 8 are layout diagrams illustrating, in detail, an embodiment where the non-display area NDA is disposed on the left side of the display panel 100 corresponding to the first side of the display panel 100. FIG. 7 is a diagram additionally illustrating an embodiment with a common electrode CE in FIG. 6, and FIG. 8 is a diagram additionally illustrating an embodiment with a light blocking layer BM in FIG. 7.

In an embodiment and referring to FIGS. 6 to 8, the first scan driver GDC1, the first emission driver EDC1, an inorganic area VAL, and the dam area DAMA may be disposed in the non-display area NDA on the first side of the display panel 100.

In an embodiment, the first scan driver GDC1 may include the write scan driver GWC, the control scan driver GCC, the initialization scan driver GIC, and the bias scan driver GBC. The write scan driver GWC, the control scan driver GCC, the initialization scan driver GIC, and the bias scan driver GBC may be sequentially disposed from the display area DA to an edge EG1 of the first side of the display panel 100. For example, the write scan driver GWC may be disposed most adjacent to the display area DA, and the bias scan driver GBC may be disposed most adjacent to the edge EG1 of the first side of the display panel 100. In addition, the control scan driver GCC may be disposed more adjacent to the write scan driver GWC than the initialization scan driver GIC is. In addition, the initialization scan driver GIC may be disposed more adjacent to the bias scan driver GBC than the control scan driver GCC is.

In an embodiment, the write scan driver GWC includes a plurality of write scan stages GWST (see FIG. 6). In the non-display area NDA on the first side of the display panel 100, the plurality of write scan stages GWST may be arranged in the second direction DR2. The plurality of write scan stages GWST are connected to each other in a cascade manner and sequentially driven in the second direction DR2, and thus, may sequentially output the write scan signals to the write scan lines GWL (see FIG. 3). Each of the plurality of write scan stages GWST may output the write scan signal to the write scan line GWL (see FIG. 3) connected thereto. To this end, each of the plurality of write scan stages GWST may include a plurality of write scan transistors GWT (see FIG. 10).

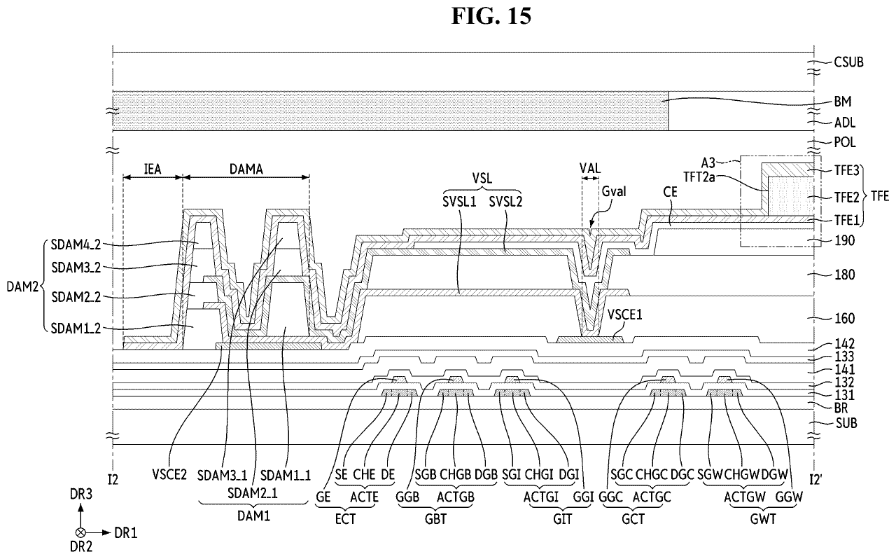

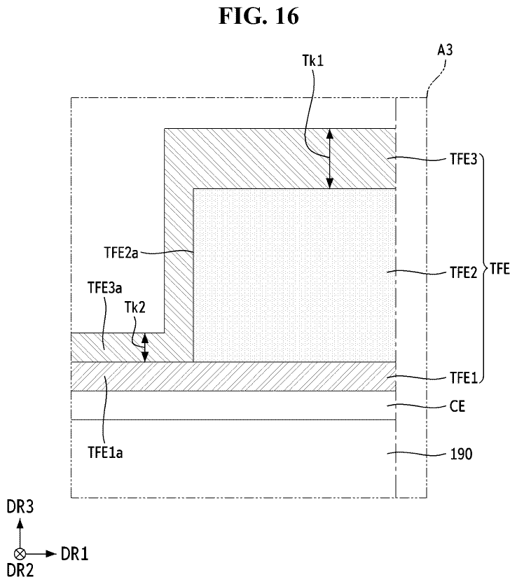

In an embodiment, the control scan driver GCC includes a plurality of control scan stages GCST. In the non-display area NDA on the first side of the display panel 100, the plurality of control scan stages GCST may be arranged in the second direction DR2. The plurality of control scan stages GCST are connected to each other in a cascade manner and sequentially driven in the second direction DR2, and thus, may sequentially output the control scan signals to the control scan lines GCL (see FIG. 3). Each of the plurality of control scan stages GCST may output the control scan signal to the control scan line GCL (see FIG. 3) connected thereto. To this end, each of the plurality of control scan stages GCST may include a plurality of control scan transistors GCT (see FIGS. 15 and 16).

In an embodiment, the initialization scan driver GIC includes a plurality of initialization scan stages GIST. In the non-display area NDA on the first side of the display panel 100, the plurality of initialization scan stages GIST may be arranged in the second direction DR2. The plurality of initialization scan stages GIST are connected to each other in a cascade manner and sequentially driven in the second direction DR2, and thus, may sequentially output the initialization scan signals to the initialization scan lines GIL (see FIG. 3). Each of the plurality of initialization scan stages GIST may output the initialization scan signal to the initialization scan line GIL (see FIG. 3) connected thereto. To this end, each of the plurality of initialization scan stages GIST may include a plurality of initialization scan transistors GIT (see FIGS. 15 and 16).

In an embodiment, the bias scan driver GBC includes a plurality of bias scan stages GBST. In the non-display area NDA on the first side of the display panel 100, the plurality of bias scan stages GBST may be arranged in the second direction DR2. The plurality of bias scan stages GBST are connected to each other in a cascade manner and sequentially driven in the second direction DR2, and thus, may sequentially output the bias scan signals to the bias scan lines GBL (see FIG. 3). Each of the plurality of bias scan stages GBST may output the bias scan signal to the bias scan line GBL (see FIG. 3) connected thereto. To this end, each of the plurality of bias scan stages GBST may include a plurality of bias scan transistors GBT (see FIG. 10).

In an embodiment, the first emission driver EDC1 includes a plurality of emission stages EST. In the non-display area NDA on the first side of the display panel 100, the plurality of emission stages EST may be arranged in the second direction DR2. The plurality of emission stages EST are connected to each other in a cascade manner and sequentially driven in the second direction DR2, and thus, may sequentially output the emission control signals to the emission control lines EML (see FIG. 3). Each of the plurality of emission stages EST may output the emission control signal to the emission control line EML (see FIG. 3) connected thereto. To this end, each of the plurality of emission stages EST may include a plurality of emission control transistors ECT (see FIG. 10).

In an embodiment, the dam area DAMA may be disposed outside the first emission driver EDC1. The dam area DAMA may be disposed closer to the edge EG1 of the first side of the display panel 100 than the first emission driver EDC1 is.

The dam area DAMA includes a first dam DAM1 and a second dam DAM2. In the non-display area NDA on the first side of the display panel 100, each of the first dam DAM1 and the second dam DAM2 may extend in the second direction DR2.

In an embodiment, the first dam DAM1 may be disposed outside the first emission driver EDC1, and the second dam DAM2 may be disposed outside the first dam DAM1. The first dam DAM1 may be disposed between the first emission driver EDC1 and the second dam DAM2. The second dam DAM2 may be disposed closer to the edge EG1 of the first side of the display panel 100 than the first dam DAM1 is.

It has been illustrated in FIGS. 6 to 8 that the dam area DAMA includes two dams DAM1 and DAM2, but the number of dams included in the dam area DAMA is not limited thereto.

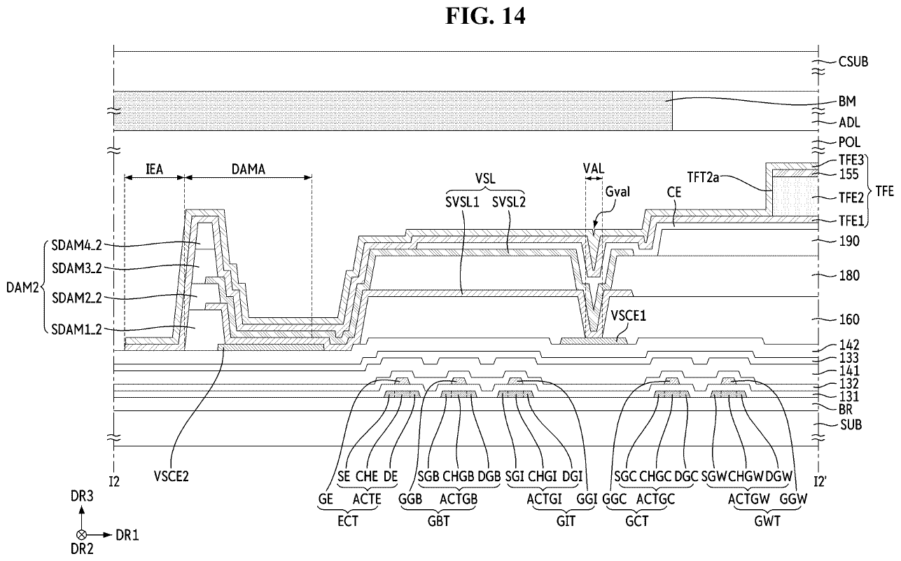

In an embodiment, the inorganic area VAL may be an area where organic layers 160 and 180 (see FIGS. 14 to 16) are removed and inorganic layers are disposed in order to prevent permeation of oxygen or moisture through the organic layers 160 and 180 (see FIGS. 14 to 16) disposed adjacent to the edge EG1 of the first side of the display panel 100. The inorganic area VAL may extend in the second direction DR2 in the non-display area NDA on the first side of the display panel 100.

In an embodiment, the inorganic area VAL may be disposed between any two drivers that are disposed adjacent to each other among the write scan driver GWC, the control scan driver GCC, the initialization scan driver GIC, and the bias scan driver GBC of the first scan driver GDC1. The inorganic area VAL may be disposed between the control scan driver GCC and the initialization scan driver GIC adjacent to each other, as illustrated in FIG. 6. In this case, the inorganic area VAL may be disposed between the control scan stages GCST and initialization scan stages GIST.

However, a position where the inorganic area VAL is disposed in an exemplary embodiment of the invention is not limited to that illustrated in FIG. 6. For example, in an embodiment, the inorganic area VAL may be disposed between the write scan driver GWC and the control scan driver GCC adjacent to each other. In this case, the inorganic area VAL may be disposed between the write scan stages GWST and the control scan stages GCST.

In another embodiment, the inorganic area VAL may be disposed between the initialization scan driver GIC and the bias scan driver GBC disposed adjacent to each other. In this case, the inorganic area VAL may be disposed between the initialization scan stages GIST and the bias scan stages GBST.

In another embodiment, the inorganic area VAL may be disposed between the bias scan driver GBC and the first emission driver EDC1. In this case, the inorganic area VAL may be disposed between the bias scan stages GBST and the emission stages EST.

In an embodiment, the inorganic area VAL may include a groove Gval (see FIG. 10) in which the organic layers 160 and 180 (see FIGS. 9 and 10) are removed. The groove Gval of the inorganic area VAL may have a cross-sectional shape grooved in a V shape like a valley.

In an embodiment and referring to FIG. 7, the common electrode CE may be disposed over the entire display area DA. In the non-display area NDA on the first side of the display panel 100, the common electrode CE may overlap the write scan driver GWC, the control scan driver GCC, and the initialization scan driver GIC of the first scan driver GDC1. In the non-display area NDA on the first side of the display panel 100, the common electrode CE may overlap the inorganic area VAL.

In an embodiment, in the non-display area NDA on the first side of the display panel 100, the common electrode CE may not overlap the bias scan driver GBC of the first scan driver GDC1 and the first emission driver EDC1, as illustrated in FIG. 7, but the invention is not limited thereto. For example, in the non-display area NDA on the first side of the display panel 100, the common electrode CE may overlap the bias scan driver GBC of the first scan driver GDC1. In addition, in the non-display area NDA on the first side of the display panel 100, the common electrode CE may overlap the first emission driver EDC1.

In an embodiment and referring to FIG. 8, in the non-display area NDA on the first side of the display panel 100, the light blocking layer BM of a cover substrate CSUB (see FIGS. 9 and 10) may overlap the dam area DAMA, the first emission driver EDC1, and the bias scan driver GBC and the initialization scan driver GIC of the first scan driver GDC1. In the non-display area NDA on the first side of the display panel 100, the light blocking layer BM of the cover substrate CSUB may overlap the inorganic area VAL.

In an embodiment, in the non-display area NDA on the first side of the display panel 100, the light blocking layer BM of the cover substrate CSUB may overlap the control scan driver GCC of the first scan driver GDC1, as illustrated in FIG. 8, but the invention is not limited thereto. For example, in the non-display area NDA on the first side of the display panel 100, the light blocking layer BM of the cover substrate CSUB may not overlap the control scan driver GCC of the first scan driver GDC1, as illustrated in FIG. 8.

In addition, in an embodiment, in the non-display area NDA on the first side of the display panel 100, the light blocking layer BM of the cover substrate CSUB may not overlap the write scan driver GWC of the first scan driver GDC1, as illustrated in FIG. 8, but the invention is not limited thereto. For example, in the non-display area NDA on the first side of the display panel 100, the light blocking layer BM of the cover substrate CSUB may overlap the write scan driver GWC of the first scan driver GDC1.

In an embodiment, the non-display area NDA on the first side of the display panel 100, the common electrode CE overlaps the inorganic area VAL, and may thus be disposed in the groove Gval (see FIG. 10) in which the organic layers 160 and 180 (see FIGS. 9 and 10 are removed. The groove Gval of the organic layers 160 and 180 may have a cross-sectional shape grooved in a V shape like a valley.

FIG. 9 is a cross-sectional view illustrating an example of a cross section of the display panel taken along line I1-I1′ of FIG. 5, according to an embodiment. FIG. 9 illustrates a cross section of the display panel 100 illustrating the first light emitting unit ELU1, the second light emitting unit ELU2, and the third light emitting unit ELU3 of the display area DA.

In an embodiment and referring to FIG. 9, a substrate SUB may be made of an insulating material such as glass or a polymer resin.

In an embodiment, a barrier film BR may be disposed on the substrate SUB, where the barrier film BR is a film for protecting thin film transistors TFT1 and TFT2 and a light emitting layer EL from moisture permeating through the substrate SUB vulnerable to moisture permeation. The barrier film BR may include a plurality of inorganic layers that are alternately stacked.

In an embodiment, a first thin film transistor TFT1 may be disposed on the barrier film BR, where the first thin film transistor TFT1 may be any one of the fifth transistor T5 and the sixth transistor T6 illustrated in FIG. 4. The first thin film transistor TFT1 may include a first active layer ACT1 and a first gate electrode G1.

In an embodiment, the first active layer ACT1 of the first thin film transistor TFT1 may be disposed on the barrier film BR, where the first active layer ACT1 of the first thin film transistor TFT1 may include polycrystalline silicon, single crystal silicon, low-temperature polycrystalline silicon, or amorphous silicon.

In an embodiment, the first active layer ACT1 may include a first channel region CHA1, a first source region S1, and a first drain region D1. The first channel region CHA1 may be a region overlapping the first gate electrode G1 in a third direction DR3, which is a thickness direction of the substrate SUB. The third direction DR3 may be defined as the thickness direction of the substrate SUB or a thickness direction of the display panel 100. The first source region S1 may be disposed on one side of the first channel region CHA1, and the first drain region D1 may be disposed on the other side of the first channel region CHA1. The first source region S1 and the first drain region D1 may be regions that do not overlap the first gate electrode G1 in the third direction DR3. The first source region S1 and the first drain region D1 may be regions having conductivity by doping a semiconductor material with ions.

In an embodiment, a first gate insulating layer 131 may be disposed on the first channel region CHA1, the first source region S1, and the first drain region D1 of the first thin film transistor TFT1.

In an embodiment, a first gate metal layer may be disposed on the first gate insulating layer 131 and may include the first gate electrode G1 of the first thin film transistor TFT1 and a first capacitor electrode CAE1. The first gate electrode G1 may overlap the first active layer ACT1 in the third direction DR3.

In an embodiment, a second gate insulating layer 132 may be disposed on the first gate electrode G1 of the first thin film transistor TFT1 and the first capacitor electrode CAE1.

In an embodiment, a second gate metal layer may be disposed on the second gate insulating layer 132, where the second gate metal layer may include a second capacitor electrode CAE2. The second capacitor electrode CAE2 may overlap the first capacitor electrode CAE1 in the third direction DR3. Since the second gate insulating layer 132 has a predetermined dielectric constant, the capacitor Cst (see FIG. 4) may be formed by the first capacitor electrode CAE1, the second capacitor electrode CAE2, and the second gate insulating layer 132 disposed between the first capacitor electrode CAE1 and the second capacitor electrode CAE2.

In an embodiment, a first interlayer insulating layer 141 may be disposed on the second capacitor electrode CAE2.

In an embodiment, a second thin film transistor TFT2 may be disposed on the first interlayer insulating layer 141. The second thin film transistor TFT2 may be any one of the second transistor T2 and the third transistor T3 illustrated in FIG. 4. The second thin film transistor TFT2 may include a second active layer ACT2 and a second gate electrode G2.

In an embodiment, the second active layer ACT2 of the second thin film transistor TFT2 may be disposed on the first interlayer insulating layer 141 and may include an oxide semiconductor. For example, the second active layer ACT2 may include IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn) and oxygen (O)).

In an embodiment, the second active layer ACT2 may include a second channel region CHA2, a second source region S2, and a second drain region D2. The second channel region CHA2 may be a region overlapping the second gate electrode G2 in the third direction DR3. The second source region S2 may be disposed on one side of the second channel region CHA2, and the second drain region D2 may be disposed on the other side of the second channel region CHA2. The second source region S2 and the second drain region D2 may be regions that do not overlap the second gate electrode G2 in the third direction DR3. The second source region S2 and the second drain region D2 may be regions having conductivity by doping an oxide semiconductor with ions.

In an embodiment, a third gate insulating layer 133 may be disposed on the second active layer ACT2 of the second thin film transistor TFT2.

In an embodiment, a third gate metal layer may be disposed on the third gate insulating layer 133. The third gate metal layer may include the second gate electrode G2 of the second thin film transistor TFT2, where the second gate electrode G2 may overlap the second active layer ACT2 in the third direction DR3.

In an embodiment, a second interlayer insulating layer 142 may be disposed on the second gate electrode G2 of the second thin film transistor TFT2.

In an embodiment, a first data metal layer may be disposed on the second interlayer insulating layer 142. The first data metal layer may include a first connection electrode BE1, a second connection electrode BE2, and a third connection electrode BE3. The first connection electrode BE1 may be connected to the first drain region D1 of the first active layer ACT1 through a first connection hole BCT1 penetrating through the first gate insulating layer 131, the second gate insulating layer 132, the first interlayer insulating layer 141, the third gate insulating layer 133, and the second interlayer insulating layer 142. The second connection electrode BE2 may be connected to the second source region S2 of the second active layer ACT2 through a second connection hole BCT2 penetrating through the second interlayer insulating layer 142. The third connection electrode BE3 may be connected to the second drain region D2 of the second active layer ACT2 through a third connection hole BCT3 penetrating through the second interlayer insulating layer 142.

In an embodiment, a first organic layer 160 for planarizing a step due to the first thin film transistor TFT1 and the second thin film transistor TFT2 may be disposed on the first connection electrode BE1, the second connection electrode BE2, and the third connection electrode BE3.

In an embodiment, a second data metal layer may be disposed on the first organic layer 160 and may include a fourth connection electrode BE4. The fourth connection electrode BE4 may be connected to the first connection electrode BE1 through a fourth connection hole BCT4 penetrating through the first organic layer 160.

In an embodiment, a second organic layer 180 may be disposed on the fourth connection electrode BE4.

In an embodiment, each of the barrier film BR, the first gate insulating layer 131, the second gate insulating layer 132, the third gate insulating layer 133, the first interlayer insulating layer 141, and the second interlayer insulating layer 142 may be formed as an inorganic layer made of silicon nitride (SiNₓ), silicon oxynitride (SiON), silicon oxide (SiOₓ), titanium oxide (TiOₓ), or aluminum oxide (AlOₓ).

In an embodiment, each of the first gate metal layer, the second gate metal layer, the third gate metal layer, the first data metal layer, and the second data metal layer may be formed as a single layer or multiple layers made of any one of molybdenum (Mo), aluminum (A1), chromium (Cr), gold (Au), titanium (Ti), nickel (Ni), neodymium (Nd), and copper (Cu), or alloys thereof.

In an embodiment, each of the first organic layer 160 and the second organic layer 180 may be formed as an organic layer made of an acrylic resin, an epoxy resin, a phenolic resin, a polyamide resin, a polyimide resin, or the like.

In an embodiment, a plurality of light emitting elements LE and a bank 190 may be disposed on the second organic layer 180. Each of the plurality of light emitting elements LE may include a pixel electrode PXE, a light emitting layer EL, and a common electrode CE. Each of the plurality of light emitting elements LE refers to an element in which holes from the pixel electrode PXE and electrons from the common electrode CE are recombined with each other in the light emitting layer EL to emit light. Each of the plurality of light emitting elements LE may be an organic light emitting diode in which the light emitting layer EL is an organic light emitting layer, but the invention is not limited thereto.

In an embodiment, a pixel electrode layer may be disposed on the second organic layer 180, where the pixel electrode layer may include the pixel electrodes PXE. Each of the pixel electrodes PXE may be connected to the fourth connection electrode BE4 through a pixel connection hole PCT penetrating through the second organic layer 180. Each of the pixel electrodes PXE may be connected to the first source region S1 or the first drain region D1 of the first thin film transistor TFT1 through the first connection electrode BE1 and the fourth connection electrode BE4. Therefore, a voltage controlled by the first thin film transistor TFT1 may be applied to each of the pixel electrodes PXE. The pixel electrode layer may be formed as a single layer or multiple layers made of any one of molybdenum (Mo), aluminum (A1), chromium (Cr), gold (Au), titanium (Ti), nickel (Ni), neodymium (Nd), and copper (Cu), or alloys thereof.

In an embodiment, the bank 190 serves to define the light emitting units ELU1, ELU2, and ELU3 of the display pixels. To this end, the bank 190 may be formed to expose a partial area of the pixel electrode PXE on the second organic layer 180. The bank 190 may cover an edge of the pixel electrode PXE.

In an embodiment, a spacer 191 for stably supporting a mask in a process of depositing the light emitting layer EL may be disposed on the bank 190.

In an embodiment, each of the bank 190 and the spacer 191 may be formed as an organic layer made of an acrylic resin, an epoxy resin, a phenolic resin, a polyamide resin, a polyimide resin, or the like.

In an embodiment, each of light emitting layers EL may be exposed without being covered by the bank 190, and may be disposed on the pixel electrode PXE corresponding thereto. Each of the light emitting layers EL may include an organic material and emit a predetermined light. For example, the light emitting layer EL of the first light emitting unit ELU1 may emit the first light, the light emitting layer EL of the second light emitting unit ELU2 may emit the second light, and the light emitting layer EL of the third light emitting unit ELU3 may emit the third light. Each of the light emitting layers EL may include a hole transporting layer, an organic material layer, and an electron transporting layer.

In an embodiment, the common electrode CE may be disposed on the light emitting layers EL and the bank 190 and may be formed to cover an upper surface of each of the light emitting layers EL and an upper surface of the bank 190. The common electrode CE may be disposed in common over the entire display area DA. The common electrode CE may also be disposed in a portion of the non-display area NDA.

In an embodiment, in a top emission structure, the common electrode CE may be made of a transparent conductive material (TCO) such as indium tin oxide (ITO) or indium zinc oxide (IZO) capable of transmitting light therethrough or a semi-transmissive conductive material such as magnesium (Mg), silver (Ag), or an alloy of magnesium (Mg) and silver (Ag). When the common electrode CE is made of the semi-transmissive conductive material, light emission efficiency of each of the light emitting elements LE may be increased by a micro cavity.

In an embodiment, an encapsulation layer TFE may be disposed on the common electrode CE, where the encapsulation layer TFE may include at least one inorganic layer in order to prevent oxygen or moisture from permeating into the light emitting layer EL. In addition, the encapsulation layer TFE may include at least one inorganic layer in order to prevent an air gap from occurring in at least one inorganic layer due to foreign substances such as dust.

In an embodiment, the encapsulation layer TFE may include a first inorganic encapsulation layer TFE1, an organic encapsulation layer TFE2, an intermediate inorganic encapsulation layer 155, and a second inorganic encapsulation layer TFE3 that are sequentially stacked. The first inorganic encapsulation layer TFE1 may be disposed on the common electrode CE, the organic encapsulation layer TFE2 may be disposed on the first inorganic encapsulation layer TFE1, the intermediate inorganic encapsulation layer 155 may be disposed on the organic encapsulation layer TFE2, and the second inorganic encapsulation layer TFE3 may be disposed on the intermediate inorganic encapsulation layer 155.

In an embodiment, an end TFE2a of the organic encapsulation layer TFE2 may be disposed in the non-display area NDA between the groove Gval and the display area DA. For example, in a plan view, the end TFE2a of the organic encapsulation layer TFE2 may be disposed in the non-display area NDA between the groove Gval and the display area DA. In addition, in a plan view, the organic encapsulation layer TFE2 may be surrounded by the groove Gval. According to still another embodiment, the end TFE2a of the organic encapsulation layer TFE2 may be disposed in the non-display area NDA between the display area DA and the first scan driver GDC1. The intermediate inorganic encapsulation layer 155 and the organic encapsulation layer TFE2 may have different ashing rates.

In an embodiment, the first inorganic encapsulation layer TFE1, the intermediate inorganic encapsulation layer 155, and the second inorganic encapsulation layer TFE3 may be formed as multiple films in which one or more inorganic layers of a silicon nitride (SiNₓ) layer, a silicon oxynitride (SiON) layer, a silicon oxide (SiOₓ) layer, a titanium oxide (TiOₓ) layer, and an aluminum oxide (AlOₓ) layer are alternately stacked. The organic encapsulation layer TFE2 may be formed as an organic layer made of an acrylic resin, an epoxy resin, a phenolic resin, a polyamide resin, or a polyimide resin.

In an embodiment, a polarizing film POL for preventing deterioration of visibility due to external light may be disposed on the encapsulation layer TFE, where the polarizing film POL may include a first base member, a linear polarizer, a phase retardation film such as a λ/4 plate (quarter-wave plate), and a second base member. In another embodiment, the polarizing film POL may be replaced with another anti-reflection layer such as a color filter layer including a plurality of color filters.

In an embodiment, a sensor electrode layer including sensor electrodes for sensing a touch may be disposed between the encapsulation layer TFE and the polarizing film POL.

In an embodiment, a cover substrate CSUB may be disposed on the polarizing film POL. The cover substrate CSUB may be attached onto the polarizing film POL by a transparent adhesive material ADL such as an optically clear adhesive (OCA) film or an optically clear resin (OCR).

FIG. 10 is a cross-sectional view illustrating an example of a cross section of the display panel taken along line I2-I2′ of FIGS. 6 to 8, according to an embodiment. FIG. 10 illustrates a cross section of the display panel 100 illustrating the non-display area NDA on the first side of the display panel 100.

In an embodiment and referring to FIG. 10, a write scan transistor GWT of the write scan stage GWST (see FIG. 6), a control scan transistor GCT of the control scan stage GCST (see FIG. 6), an initialization scan transistor GIT of the initialization scan stage GIST (see FIG. 6), a bias scan transistor GBT of the bias scan stage GBST (see FIG. 6), and an emission control transistor ECT of the emission stage EST (see FIG. 6) may be disposed on the barrier film BR.

In an embodiment, the write scan transistor GWT may include a write active layer ACTGW and a write gate electrode GGW. The write active layer ACTGW may include a write channel region CHGW, a write source region SGW, and a write drain region DGW. The write active layer ACTGW may be disposed on the barrier film BR. The write gate electrode GGW may overlap the write channel region CHGW in the third direction DR3, and may be disposed on the first gate insulating layer 131.

In an embodiment, the control scan transistor GCT may include a control active layer ACTGC and a control gate electrode GGC. The control active layer ACTGC may include a control channel region CHGC, a control source region SGC, and a control drain region DGC. The control active layer ACTGC may be disposed on the barrier film BR. The control gate electrode GGC may overlap the control channel region CHGC in the third direction DR3, and may be disposed on the first gate insulating layer 131.

In an embodiment, the initialization scan transistor GIT may include an initialization active layer ACTGI and an initialization gate electrode GGI. The initialization active layer ACTGI may include an initialization channel region CHGI, an initialization source region SGI, and an initialization drain region DGI. The initialization active layer ACTGI may be disposed on the barrier film BR. The initialization gate electrode GGI may overlap the initialization channel region CHGI in the third direction DR3, and may be disposed on the first gate insulating layer 131.

In an embodiment, the bias scan transistor GBT may include a bias active layer ACTGB and a bias gate electrode GGB. The bias active layer ACTGB may include a bias channel region CHGB, a bias source region SGB, and a bias drain region DGB. The bias active layer ACTGB may be disposed on the barrier film BR. The bias gate electrode GGB may overlap the bias channel region CHGB in the third direction DR3, and may be disposed on the first gate insulating layer 131.

In an embodiment, the emission control transistor ECT may include an emission active layer ACTE and an emission gate electrode GE. The emission active layer ACTE may include an emission channel region CHE, an emission source region SE, and an emission drain region DE. The emission active layer ACTE may be disposed on the barrier film BR. The emission gate electrode GE may overlap the emission channel region CHE in the third direction DR3, and may be disposed on the first gate insulating layer 131.

In an embodiment, each of the write active layer ACTGW, the control active layer ACTGC, the initialization active layer ACTGI, the bias active layer ACTGB, and the emission active layer ACTE may include polycrystalline silicon, single crystal silicon, low-temperature polycrystalline silicon, or amorphous silicon. The first gate metal layer may include the write gate electrode GGW, the control gate electrode GGC, the initialization gate electrode GGI, the bias gate electrode GGB, and the emission gate electrode GE.

In an embodiment, the groove Gval penetrating through the first organic layer 160 and the second organic layer 180 may be disposed in the inorganic area VAL. The first organic layer 160 and the second organic layer 180 disposed adjacent to the edge EG1 of the first side of the display panel 100 in the inorganic area VAL may be spaced apart from the first organic layer 160 and the second organic layer 180 disposed adjacent to the display area DA. In the inorganic area VAL, the first organic layer 160 and the second organic layer 180 may be disconnected. Therefore, even though oxygen or moisture permeates through the first organic layer 160 and the second organic layer 180 at the edge EG1 of the first side of the display panel 100, it is possible to prevent the oxygen or the moisture from being transferred to the first organic layer 160 and the second organic layer 180 disposed adjacent to the display area DA to affect the light emitting layer EL. In a plan view, the groove Gval may have a shape of a closed curve surrounding the display area DA.

In an embodiment, the first data metal layer may include a first power connection electrode VSCE1 and a second power connection electrode VSCE2. The first power connection electrode VSCE1 and the second power connection electrode VSCE2 may be disposed on the second interlayer insulating layer 142.

In an embodiment, the first power connection electrode VSCE1 may be disposed in the groove Gval penetrating through the first organic layer 160 and the second organic layer 180. The groove Gval may have a V-shaped cross-sectional shape.

In an embodiment, the second power connection electrode VSCE2 may be disposed on the second interlayer insulating layer 142 exposed without being covered by the first organic layer 160 in the dam area DAMA.

In an embodiment, the first power line VSL includes a first sub-power line SVSL1 and a second sub-power line SVSL2.

In an embodiment, the first sub-power line SVSL1 may be disposed on the first organic layer 160. The first sub-power line SVSL1 may be connected to the first power connection electrode VSCE1 exposed in the groove Gval of the inorganic area VAL. The first sub-power line SVSL1 may be disposed on the second power connection electrode VSCE2 in the dam area DAMA.

In an embodiment, the second sub-power line SVSL2 may be disposed on the second organic layer 180. The second sub-power line SVSL2 may be disposed on the first sub-power line SVSL1 in the groove Gval of the inorganic area VAL. The second sub-power line SVSL2 may be disposed on the first sub-power line SVSL1 in the dam area DAMA.

For example, in an embodiment, the second power connection electrode VSCE2, the first sub-power line SVSL1, and the second sub-power line SVSL2 may be sequentially stacked in the dam area DAMA.

In an embodiment, the first sub-power line SVSL1 and the second sub-power line SVSL2 may overlap the initialization scan driver GIC, the bias scan driver GBC, and the first emission driver EDC1 disposed between the inorganic area VAL and the dam area DAMA.

In an embodiment, the common electrode CE may be disposed on the second organic layer 180 to be exposed without being covered by the bank 190. The common electrode CE may be connected to the second sub-power line SVSL2 in the groove Gval of the inorganic area VAL. The common electrode CE may be disposed on sidewalls of the groove Gval of the inorganic area VAL. For this reason, when external light is incident on the groove Gval of the inorganic area VAL, the external light may be unpredictably diffusely reflected by the common electrode CE disposed on the sidewalls of the groove Gval of the inorganic area VAL.

In an embodiment, the first dam DAM1 and the second dam DAM2 may be disposed on the first power line VSL.

In an embodiment, the first dam DAM1 and the second dam DAM2 may be structures for preventing the organic encapsulation layer TFE2 from overflowing onto the edge EG1 of the first side of the display panel 100. The first dam DAM1 and the second dam DAM2 may be structures for confining the organic encapsulation layer TFE2.

In an embodiment, the first dam DAM1 may include a first sub-dam SDAM1_1, a second sub-dam SDAM2_1, and a third sub-dam SDAM3_1 that are sequentially stacked on the first power line VSL. The first sub-dam SDAM1_1 may be made of the same material as the second organic layer 180, the second sub-dam SDAM2_1 may be made of the same material as the bank 190, and the third sub-dam SDAM3_1 may be made of the same material as the spacer 191.

In an embodiment, the second sub-power line SVSL2 may be disposed on the first sub-dam SDAM1_1 of the first dam DAM1. The second sub-power line SVSL2 may be disposed to cover the first sub-dam SDAM1_1 of the first dam DAM1. For example, the second sub-power line SVSL2 may be disposed on an upper surface and side surfaces of the first sub-dam SDAM1_1 of the first dam DAM1. The second sub-dam SDAM2_1 of the first dam DAM1 may be disposed on the second sub-power line SVSL2.

In an embodiment, the second dam DAM2 may include a first sub-dam SDAM1_2, a second sub-dam SDAM2_2, a third sub-dam SDAM3_2, and a fourth sub-dam SDAM4_2 that are sequentially stacked on the second interlayer insulating layer 142. The first sub-dam SDAM1_2 may be made of the same material as the first organic layer 160, and the second sub-dam SDAM2_2 may be made of the same material as the second organic layer 180. The third sub-dam SDAM3_2 may be made of the same material as the bank 190, and the fourth sub-dam SDAM4_2 may be made of the same material as the spacer 191.

In an embodiment, the first sub-dam SDAM1_2 of the second dam DAM2 may be disposed on the second power connection electrode VSCE2. In addition, the first sub-power line SVSL1 may be disposed on the first sub-dam SDAM1_2 of the second dam DAM2, and the second sub-dam SDAM2_2 of the second dam DAM2 may be disposed on the first sub-power line SVSL1. In addition, the second sub-power line SVSL2 may be disposed on the second sub-dam SDAM2_2 of the second dam DAM2, and the third sub-dam SDAM3_2 of the second dam DAM2 may be disposed on the second sub-power line SVSL2.

In an embodiment, outside the second dam DAM2, the first inorganic encapsulation layer TFE1 and the second inorganic encapsulation layer TFE3 are in contact with each other, such that an inorganic encapsulation area IEA including only inorganic layers may be disposed. An organic layer is not disposed in the inorganic encapsulation area IEA. The display area DA is surrounded by the inorganic encapsulation area IEA, and it is thus possible to prevent external oxygen or moisture from permeating into the light emitting layer EL of the display area DA. The inorganic encapsulation area IEA may be disposed adjacent to the edge EG1 (see FIGS. 6 to 8) of the first side of the display panel 100. The inorganic encapsulation area IEA may be disposed to be more adjacent to the dam area DAMA than the inorganic area VAL.

In an embodiment, the light blocking layer BM may be disposed on one surface of the cover substrate CSUB and may overlap the groove Gval of the inorganic area VAL in the third direction DR3.

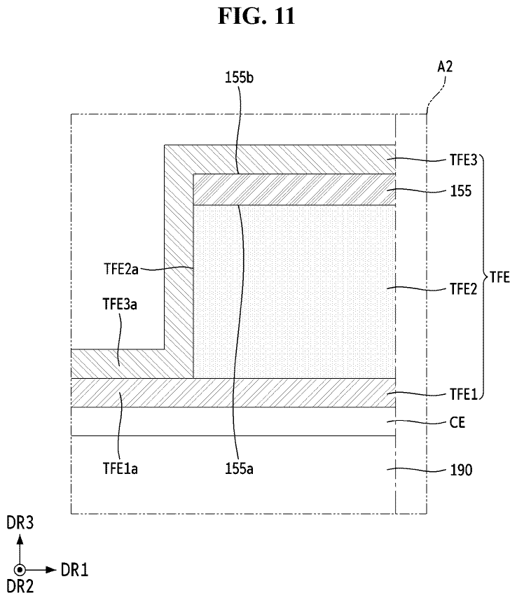

FIG. 11 is an enlarged view of area A2 of FIG. 10, according to an embodiment.

In an embodiment, the encapsulation layer TFE may include a first inorganic encapsulation layer TFE1, an organic encapsulation layer TFE2, an intermediate inorganic encapsulation layer 155, a second inorganic encapsulation layer TFE3.

In an embodiment, the outermost encapsulation layers (e.g., TFE1 and TFE3) of the encapsulation layer TFE may extend longer than the other layers (e.g., TFE2 and 155) of the encapsulation layer TFE in the non-display area NDA. For example, the outermost encapsulation layers of the layers of the encapsulation layer TFE may extend longer than the other layers of the encapsulation layer, for example, in the first direction DR1, a direction reverse to the first direction DR1 (hereinafter referred to as a first reverse direction), the second direction DR2, and a direction reverse to the second direction DR2 (hereinafter referred to as a second reverse direction), in the non-display area NDA. For example, each of the first inorganic encapsulation layer TFE1 positioned at the lowermost layer in the encapsulation layer TFE and the second inorganic encapsulation layer TFE3 positioned at the uppermost layer in the encapsulation layer TFE may extend longer than layers (for example, the organic encapsulation layer TFE2 and the intermediate inorganic encapsulation layer 155) positioned between the first inorganic encapsulation layer TFE1 and the second inorganic encapsulation layer TFE3. For example, the first inorganic encapsulation layer TFE1 and the second inorganic encapsulation layer TFE3 may include extension portions TFE1a and TFE3a, respectively.

Accordingly, in an embodiment, in a plan view, the outermost encapsulation layers may have a shape in which ends (or edges) thereof surround the other layers of the encapsulation layer TFE. For example, in a plan view, each end (or edge) of the first inorganic encapsulation layer TFE1 and the second inorganic encapsulation layer TFE3 may surround the layers (e.g., the organic encapsulation layer TFE2 and the intermediate inorganic encapsulation layer 155) positioned between the first inorganic encapsulation layer TFE1 and the second inorganic encapsulation layer TFE3.

In an embodiment and in the non-display area NDA, the extension portions TFE1a and TFE3a of the outermost encapsulation layers may be in contact with each other. For example, in the non-display area NDA, the extension portion TFE1a of the first inorganic encapsulation layer TFE1 and the extension portion TFE3a of the second inorganic encapsulation layer TFE3 may be in direct contact with each other. Accordingly, the organic encapsulation layer TFE2 and the intermediate inorganic encapsulation layer 155 may be surrounded by the first inorganic encapsulation layer TFE1 and the second inorganic encapsulation layer TFE3.

In an embodiment, the intermediate inorganic encapsulation layer 155 and the second inorganic encapsulation layer TFE3 in contact with each other may be made of different materials. For example, when the intermediate inorganic encapsulation layer 155 is made of a material including any one of silicon nitride (SiNₓ), silicon oxynitride (SiON), silicon oxide (SiOₓ), titanium oxide (TiOₓ), or aluminum oxide (AlOₓ), the second inorganic encapsulation layer TFE3 may be made of a material including another of silicon nitride (SiNₓ), silicon oxynitride (SiON), silicon oxide (SiOₓ), titanium oxide (TiOₓ), or aluminum oxide (AlOₓ).

In an embodiment, the number of inorganic layers disposed on the organic encapsulation layer TFE2 and the number of inorganic layers disposed below the organic encapsulation layer TFE2 may be different from each other. For example, the number of inorganic layers continuously disposed directly above the organic encapsulation layer TFE2 in the third direction DR3 and the number of inorganic layers continuously disposed directly below the organic encapsulation layer TFE2 in a direction which is reverse to the third direction DR3 (hereinafter referred to as a third reverse direction) may be different from each other. According to an embodiment, the number of inorganic layers 155 and TFE3 continuously disposed directly above the organic encapsulation layer TFE2 may be two, and the number of inorganic layers TFE1 continuously disposed directly below the organic encapsulation layer TFE2 may be one. In other words, the number of inorganic layers continuously disposed directly above the organic encapsulation layer TFE2 may be greater than the number of inorganic layers continuously disposed directly below the organic encapsulation layer TFE2 between the organic encapsulation layer TFE2 and the common electrode.

In an embodiment, the intermediate inorganic encapsulation layer 155 may be disposed between the organic encapsulation layer TFE2 and the second inorganic encapsulation layer TFE3. For example, the intermediate inorganic encapsulation layer 155 may be disposed between the organic encapsulation layer TFE2 and the second inorganic encapsulation layer TFE3 in the third direction DR3. The intermediate inorganic encapsulation layer 155 may be surrounded by the organic encapsulation layer TFE2 and the second inorganic encapsulation layer TFE3.

In an embodiment, one of surfaces of the intermediate inorganic encapsulation layer 155 opposing each other (e.g., surfaces of the intermediate inorganic encapsulation layer 155 opposing each other in the third direction DR3) may be in contact with the organic encapsulation layer TFE2, and the other of the surfaces of the intermediate inorganic encapsulation layer 155 opposing each other may be in contact with the second inorganic encapsulation layer TFE3. For example, a lower surface 155a of the intermediate inorganic encapsulation layer 155 may be in direct contact with the organic encapsulation layer TFE2, and an upper surface 155b of the intermediate inorganic encapsulation layer 155 may be in direct contact with the second inorganic encapsulation layer TFE3.

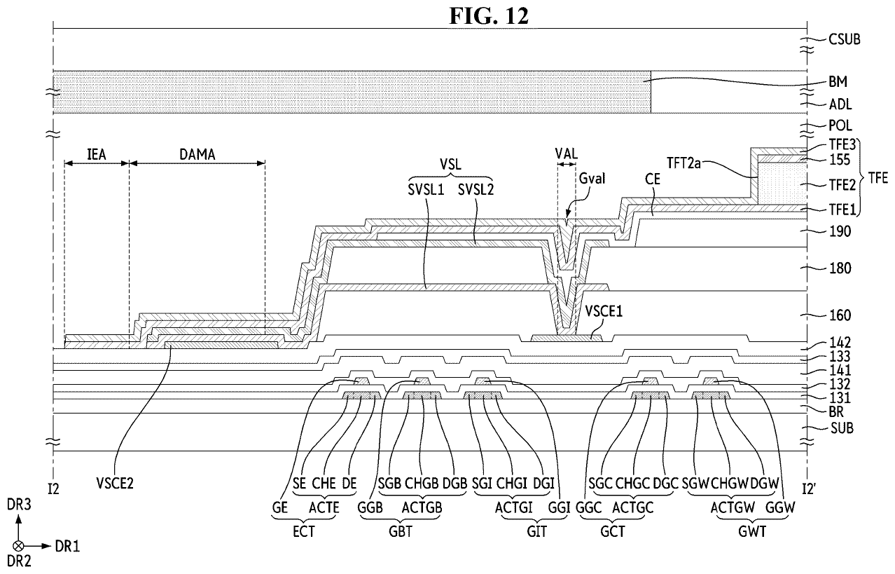

FIG. 12 is a cross-sectional view illustrating an example of a cross section of a display panel 100 taken along line I2-I2′ of FIGS. 6 to 8, according to an embodiment.

In an embodiment, a display panel 100 of FIG. 12 is different from the display panel 100 of FIGS. 9 and 10 in that it does not include the first dam DAM1 and the second dam DAM2, and such a difference will be mainly described below.

In an embodiment and as illustrated in FIG. 12, the first dam DAM1 and the second dam DAM2 may not be disposed in the dam area DAMA. For example, according to an exemplary embodiment, the organic encapsulation layer TFE2 is formed inside the groove Gval, and thus, a dam for preventing a flow of an organic layer (e.g., an organic material layer for forming the organic encapsulation layer TFE2) to the outside of the display panel 100 during a fabricating process of the display device may not be required.

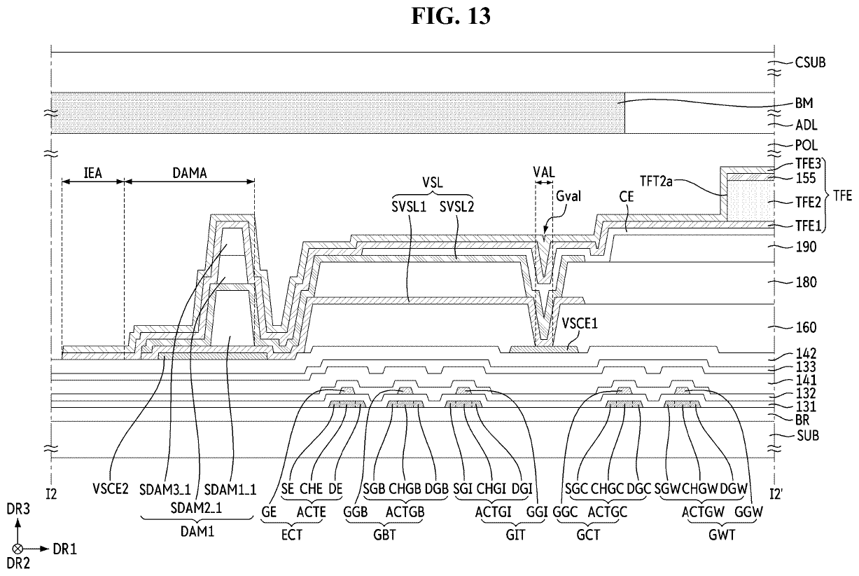

FIG. 13 is a cross-sectional view illustrating an example of a cross section of a display panel 100 taken along line I2-I2′ of FIGS. 6 to 8, according to an embodiment.

In an embodiment, a display panel 100 of FIG. 13 is different from the display panel 100 of FIGS. 9 and 10 in that it includes only the first dam DAM1 of the first dam DAM1 and the second dam DAM2, and such a difference will be mainly described below.

In an embodiment and as illustrated in FIG. 13, the first dam DAM1 may be disposed in the dam area DAMA. For example, according to an embodiment, the organic encapsulation layer TFE2 is formed inside the groove Gval, and thus, only any one of dams for preventing a flow of an organic layer to the outside of the display panel 100 during a fabricating process of the display device may be required.

FIG. 14 is a cross-sectional view illustrating an example of a cross section of a display panel 100 taken along line I2-I2′ of FIGS. 6 to 8, according to an embodiment.

In an embodiment, a display panel 100 of FIG. 14 is different from the display panel 100 of FIGS. 9 and 10 in that it includes only the second dam DAM2 of the first dam DAM1 and the second dam DAM2, and such a difference will be mainly described below.

In an embodiment and as illustrated in FIG. 14, the second dam DAM2 may be disposed in the dam area DAMA. For example, according to an embodiment, the organic encapsulation layer TFE2 is formed inside the groove Gval, and thus, only any one of dams for preventing a flow of an organic layer to the outside of the display panel 100 during a fabricating process of the display device may be required.

FIG. 15 is a cross-sectional view illustrating an example of a cross section of a display panel 100 taken along line I2-I2′ of FIGS. 6 to 8, according to an embodiment, and FIG. 16 is an enlarged view of area A3 of FIG. 15, according to an embodiment.

In an embodiment, a display panel 100 of FIGS. 15 and 16 is different from the display panel 100 of FIGS. 9 and 10 in that a thickness of the second inorganic encapsulation layer TFE3 on the organic encapsulation layer TFE2 is different, and such a difference will be mainly described below.

In an embodiment and as illustrated in FIG. 15, the encapsulation layer TFE may include a first inorganic encapsulation layer TFE1, an organic encapsulation layer TFE2, and a second inorganic encapsulation layer TFE3 that are sequentially stacked along the third direction DR3. For example, the first inorganic encapsulation layer TFE1 may be disposed on the common electrode, the organic encapsulation layer TFE2 may be disposed on the first inorganic encapsulation layer TFE1, and the second inorganic encapsulation layer TFE3 may be disposed on the organic encapsulation layer TFE2. When the encapsulation layer TFE includes the first inorganic encapsulation layer TFE1, the organic encapsulation layer TFE2, and the second inorganic encapsulation layer TFE3 as illustrated in FIG. 15, the encapsulation layer TFE of the display area DA of FIG. 9 may also include a first inorganic encapsulation layer TFE1, an organic encapsulation layer TFE2, and a second inorganic encapsulation layer TFE3 as illustrated in FIG. 15.

In an embodiment and as described above, in the non-display area NDA, the extension portion TFE1a of the first inorganic encapsulation layer TFE1 and the extension portion TFE3a of the second inorganic encapsulation layer TFE3 may be in contact with each other.

In an embodiment and as illustrated in FIG. 16, the second inorganic encapsulation layer TFE3 may have a greater thickness on the organic encapsulation layer TFE2 than on the extension portion TFE1a of the first inorganic encapsulation layer TFE1 (Tk1>Tk2). For example, a thickness Tk1 of the second inorganic encapsulation layer TFE3 overlapping the organic encapsulation layer TFE2 may be greater than a thickness Tk2 of the second inorganic encapsulation layer TFE3 overlapping the first inorganic encapsulation layer TFE1.

According to an embodiment, when the second inorganic encapsulation layer TFE3 has the greater thickness on the organic encapsulation layer TFE2 than on the extension portion TFE1a of the first inorganic encapsulation layer TFE1 in the non-display area NDA as illustrated in FIG. 16, the second inorganic encapsulation layer TFE3 may also have a greater thickness on the organic encapsulation layer TFE2 than on the extension portion TFE1a of the first inorganic encapsulation layer TFE1 in the display area DA of FIG. 9.

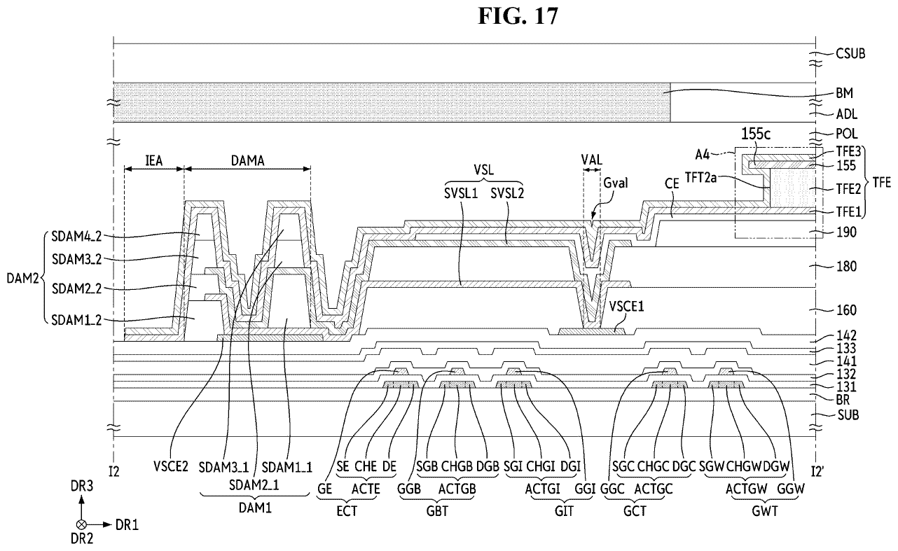

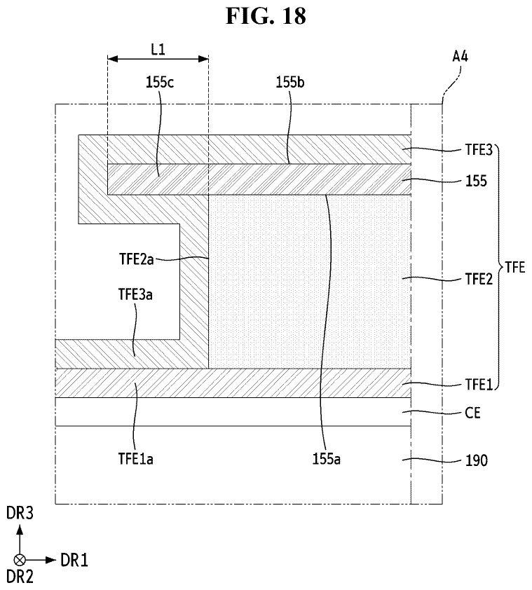

FIG. 17 is a cross-sectional view illustrating an example of a cross section of a display panel 100 taken along line I2-I2′ of FIGS. 6 to 8, according to an embodiment, and FIG. 18 is an enlarged view of area A3 of FIG. 17, according to an embodiment.

In an embodiment, a display panel 100 of FIGS. 17 and 18 is different from the display panel 100 of FIGS. 9 and 10 in that the intermediate inorganic encapsulation layer 155 further includes a protrusion portion 155c, and such a difference will be mainly described below.

In an embodiment and as illustrated in FIGS. 17 and 18, the intermediate inorganic encapsulation layer 155 of the encapsulation layer TFE may extend longer than the organic encapsulation layer TFE2 of the encapsulation layer TFE. For example, the intermediate inorganic encapsulation layer 155 may include the protrusion portion 155c extending more than the organic encapsulation layer TFE2 along the first direction DR1, the first reverse direction, the second direction DR2, and the second reverse direction. Accordingly, in a plan view, an end (or an edge) of the intermediate inorganic encapsulation layer 155 may surround the organic encapsulation layer TFE2.

In an embodiment, the protrusion portion 155c of the intermediate inorganic encapsulation layer 155 does not overlap the organic encapsulation layer TFE2 in the third direction DR3. However, the remaining portion of the intermediate inorganic encapsulation layer 155 excluding the protrusion portion 155c may overlap the organic encapsulation layer TFE2 in the third direction DR3. A length L1 of the protrusion portion 155c of the intermediate inorganic encapsulation layer 155 may be, for example, smaller than or equal to about 20 μm.

In an embodiment, the second inorganic encapsulation layer TFE3 may be disposed on the intermediate inorganic encapsulation layer 155. In this case, the second inorganic encapsulation layer TFE3 may also be disposed on the protrusion portion 155c of the intermediate inorganic encapsulation layer 155. The second inorganic encapsulation layer TFE3 may surround the intermediate inorganic encapsulation layer 155 including the protrusion portion 155c together with the organic encapsulation layer TFE2.

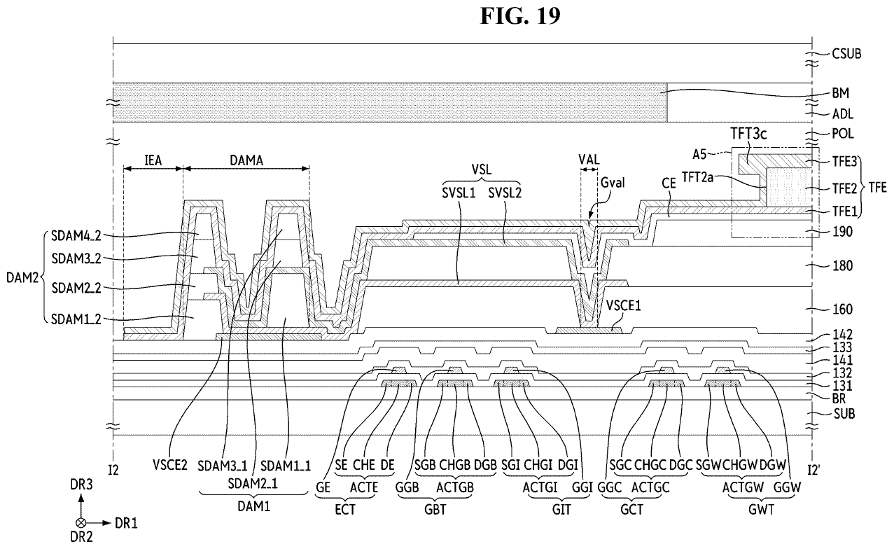

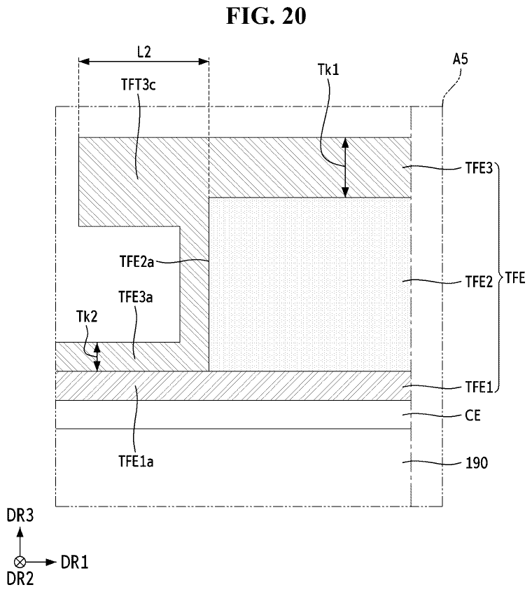

FIG. 19 is a cross-sectional view illustrating an example of a cross section of a display panel 100 taken along line I2-I2′ of FIGS. 6 to 8, according to an embodiment, and FIG. 20 is an enlarged view of area A5 of FIG. 19, according to an embodiment.

In an embodiment, a display panel 100 of FIGS. 19 and 20 is different from the display panel 100 of FIGS. 9 and 10 in that the second inorganic encapsulation layer TFE3 further includes a protrusion portion TFT3c, and such a difference will be mainly described below.

In an embodiment and as illustrated in FIGS. 19 and 20, the second inorganic encapsulation layer TFE3 of the encapsulation layer TFE may extend longer than the organic encapsulation layer TFE2 of the encapsulation layer TFE. For example, the second inorganic encapsulation layer TFE3 may include the protrusion portion TFT3c extending more than the organic encapsulation layer TFE2 along the first direction DR1, the first reverse direction, the second direction DR2, and the second reverse direction. Accordingly, in a plan view, an end (or an edge) of the second inorganic encapsulation layer TFE3 may surround the organic encapsulation layer TFE2.

In an embodiment, the protrusion portion TFT3c of the second inorganic encapsulation layer TFE3 does not overlap the organic encapsulation layer TFE2 in the third direction DR3. However, the remaining portion of the second inorganic encapsulation layer TFE3 excluding the protrusion portion TFT3c may overlap the organic encapsulation layer TFE2 in the third direction DR3. A length L2 of the protrusion portion TFT3c of the second inorganic encapsulation layer TFE3 may be, for example, smaller than or equal to about 20 μm.

In an embodiment, the second inorganic encapsulation layer TFE3 may have a greater thickness on the organic encapsulation layer TFE2 than on the extension portion TFE1a of the first inorganic encapsulation layer TFE1 (Tk1>Tk2). For example, a thickness Tk1 of the second inorganic encapsulation layer TFE3 overlapping the organic encapsulation layer TFE2 may be greater than a thickness Tk2 of the second inorganic encapsulation layer TFE3 overlapping the first inorganic encapsulation layer TFE1.

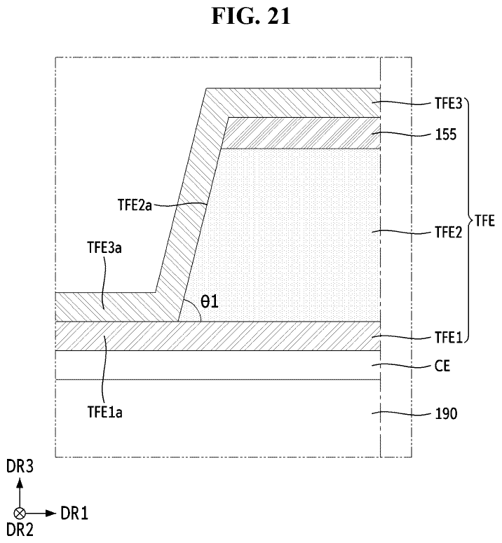

FIG. 21 is a cross-sectional view of an encapsulation layer, according to an embodiment.

In an embodiment, an end TFE2a of the organic encapsulation layer TFE2 of the encapsulation layer TFE may have an inclined surface. For example, at the end TFE2a of the organic encapsulation layer TFE2, an angle θ1 formed by a lower surface of the organic encapsulation layer TFE2 (e.g., an interface between the first inorganic encapsulation layer TFE1 and the organic encapsulation layer TFE2) and the end TFE2a of the organic encapsulation layer TFE2 may be an acute angle. The angle θ1 formed by the lower surface of the organic encapsulation layer TFE2 and the end TFE2a of the organic encapsulation layer TFE2 may be, for example, greater than or equal to about 20° and smaller than about 90°. To this end, according to an embodiment, a width of the organic encapsulation layer TFE2 may gradually decrease along a direction from the lower surface of the organic encapsulation layer TFE2 toward an upper surface of the organic encapsulation layer TFE2 (e.g., an interface between the organic encapsulation layer TFE2 and the intermediate inorganic encapsulation layer 155). For example, the width of the organic encapsulation layer TFE2 may gradually decrease along the third direction DR3. Here, the width of the organic encapsulation layer TFE2 may be, for example, a size of the organic encapsulation layer TFE2 in the first direction DR1.

In an embodiment, the end of the organic encapsulation layer TFE2 of FIGS. 10 to 20 described above may have the same oblique line shape as the end of the organic encapsulation layer TFE2 of FIG. 21.

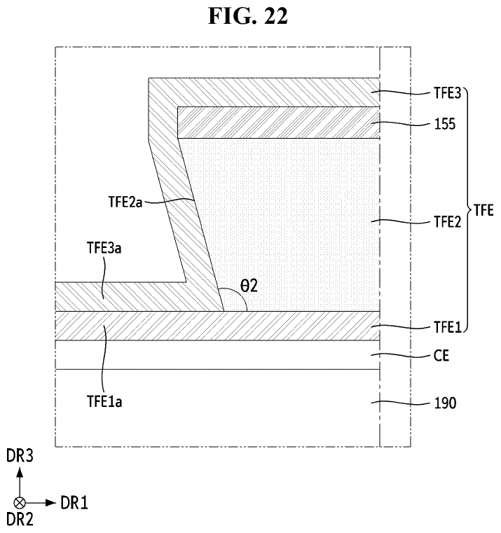

FIG. 22 is a cross-sectional view of an encapsulation layer, according to an embodiment.

In an embodiment, an end TFE2a of the organic encapsulation layer TFE2 of the encapsulation layer TFE may have an inclined surface. For example, at the end of the organic encapsulation layer TFE2, an angle θ2 formed by a lower surface of the organic encapsulation layer TFE2 (e.g., an interface between the first inorganic encapsulation layer TFE1 and the organic encapsulation layer TFE2) and the end TFE2a of the organic encapsulation layer TFE2 may be an obtuse angle. The angle θ2 formed by the lower surface of the organic encapsulation layer TFE2 and the end TFE2a of the organic encapsulation layer TFE2 may be, for example, greater than or equal to about 90° and smaller than or equal to about 120°. To this end, according to an embodiment, a width of the organic encapsulation layer TFE2 may gradually increase in a direction from the lower surface the organic encapsulation layer TFE2 toward an upper surface of the organic encapsulation layer TFE2. For example, the width of the organic encapsulation layer TFE2 may gradually increase along the third direction DR3. Here, the width of the organic encapsulation layer TFE2 may be, for example, a size of the organic encapsulation layer TFE2 in the first direction DR1.

In an embodiment, the end of the organic encapsulation layer TFE2 of FIGS. 10 to 20 described above may have the same oblique line shape as the end of the organic encapsulation layer TFE2 of FIG. 21.

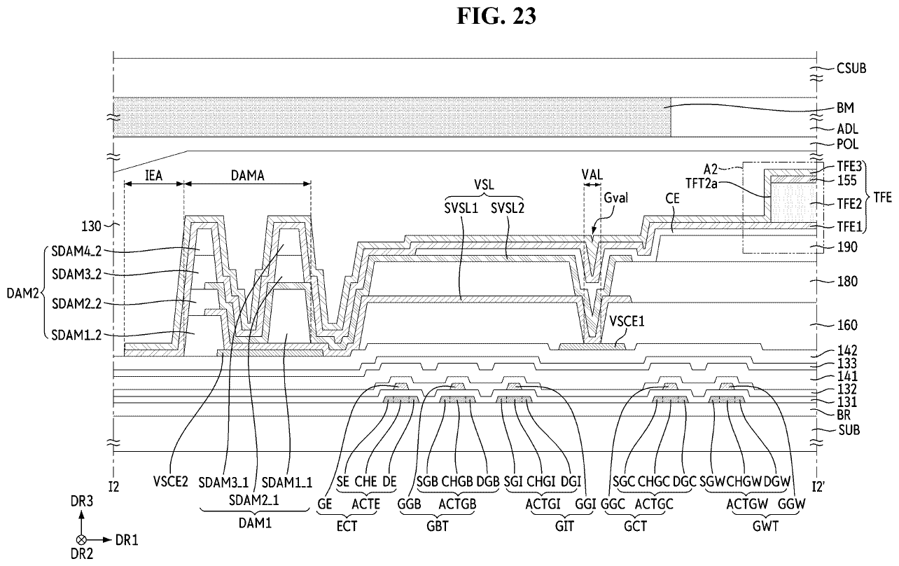

FIG. 23 is a cross-sectional view illustrating an example of a cross section of a display panel 100 taken along line I2-I2′ of FIGS. 6 to 8, according to an embodiment.

In an embodiment, a display panel 100 of FIG. 23 is different from the display panel 100 described above with reference to FIG. 10 in that it further includes an organic layer 130, and such a difference will be mainly described below.

In an embodiment ands illustrated in FIG. 23, the organic layer 130 may be further disposed on the encapsulation layer TFE. For example, the organic layer 130 may be disposed between the encapsulation layer TFE and the polarizing film POL. In this case, the organic layer 130 may be disposed on an entire surface of the substrate SUB including the encapsulation layer TFE.

In an embodiment, the organic layer 130 may be formed as an organic layer made of an acrylic resin, an epoxy resin, a phenolic resin, a polyamide resin, or a polyimide resin.

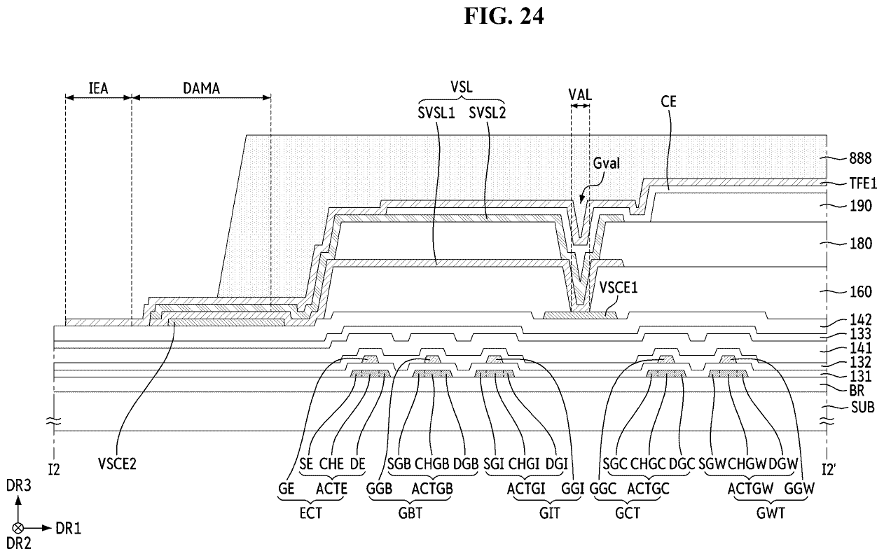

FIGS. 24 to 27 are cross-sectional views for describing processes of a method of fabricating the display device 10, according to an embodiment.

First, in an embodiment and as illustrated in FIG. 24, the first inorganic encapsulation layer TFE1 may be disposed on the common electrode CE. For example, the first inorganic encapsulation layer TFE1 may be deposited through a deposition process in a first chamber. Thereafter, the substrate SUB on which the first inorganic encapsulation layer TFE1 is disposed may be moved to a second chamber. In the second chamber, an organic layer 888 may be disposed on the first inorganic encapsulation layer TFE1 through a printing process. In this case, the organic layer 888 may be disposed up to a portion of the dam area DAMA. However, the invention is not limited thereto, and the organic layer 888 may also be disposed up to an inner side of the dam area DAMA so as to overlap the common electrode CE and so as not to overlap the dam area DAMA.

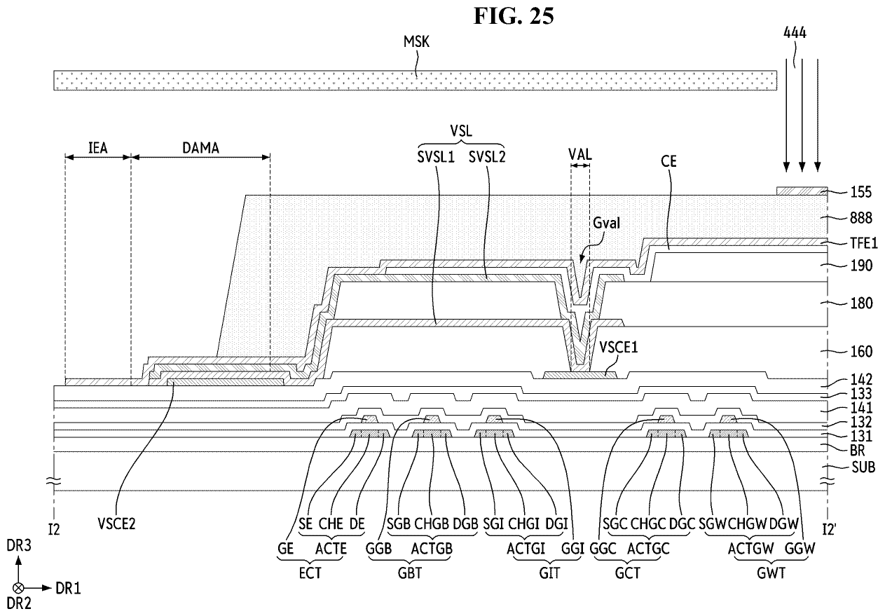

Thereafter, the substrate SUB in the second chamber may be moved to a third chamber. In an embodiment and as illustrated in FIG. 25, the intermediate inorganic encapsulation layer 155 may be disposed on the organic layer 888 through a deposition process in the third chamber. For example, the intermediate inorganic encapsulation layer 155 may be formed by disposing a deposition mask MSK on the organic layer 888 and then depositing a deposition material on the organic layer 888 through an opening 444 of the deposition mask MSK, in the third chamber. Accordingly, the intermediate inorganic encapsulation layer 155 may selectively hide only a portion of the organic layer 888. In this case, an end of the intermediate inorganic encapsulation layer 155 may be disposed in the non-display area NDA between the scan driver (e.g., the first scan driver GDC1) and the display area. Meanwhile, the intermediate inorganic encapsulation layer 155 may also be disposed in the display area DA. For example, the intermediate inorganic encapsulation layer 155 may also be disposed on the organic layer 888 of the display area DA. Meanwhile, the intermediate inorganic encapsulation layer 155 and the organic layer 888 may have different ashing rates.

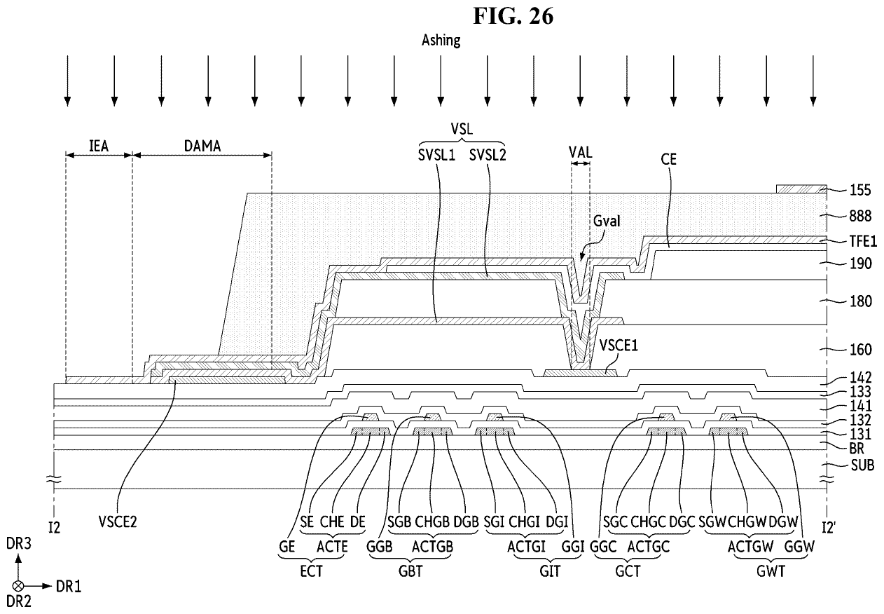

Subsequently, in an embodiment and as illustrated in FIG. 26, a process of removing the exposed organic layer 888 using the intermediate inorganic encapsulation layer 155 as a mask (e.g., a hard mask) may be performed. The organic layer 888 exposed through the intermediate inorganic encapsulation layer 155 may be removed by an ashing method using at least one of plasma, heat, and laser, for example.

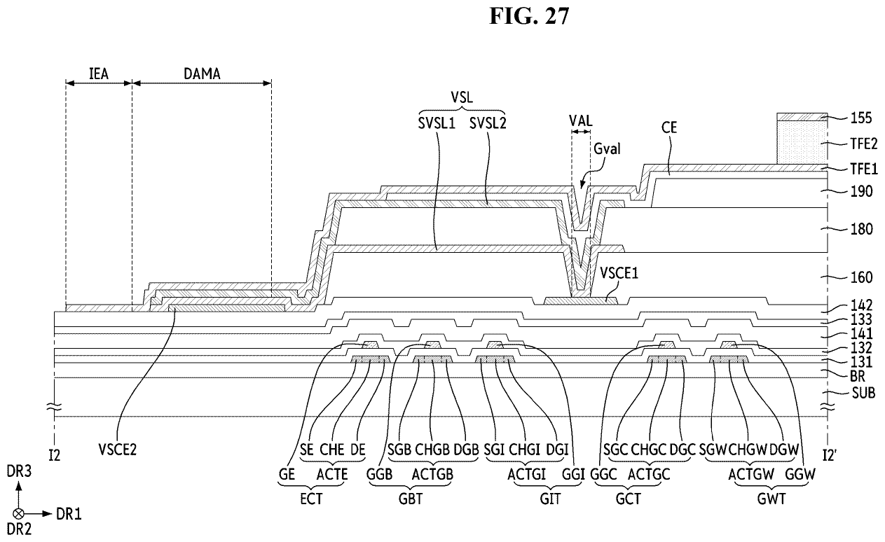

In an embodiment, when a portion of the organic layer 888 is removed by an ashing process, the organic encapsulation layer TFE2 may be formed between the intermediate inorganic encapsulation layer 155 and the first inorganic encapsulation layer TFE1, as illustrated in FIG. 27. Meanwhile, the organic layer 888 may be removed anisotropically or isotropically depending on the ashing method. For example, depending on the ashing method, instead of the organic encapsulation layer TFE2 having a form of FIG. 27, the organic encapsulation layer TFE2 having a form of any one of FIGS. 17, 21, and 22 may be formed.

Thereafter, in an embodiment and as illustrated in FIG. 12, the second inorganic encapsulation layer TFE3 may be disposed on the intermediate inorganic encapsulation layer 155. In this case, the second inorganic encapsulation layer TFE3 may cover a side surface of the intermediate inorganic encapsulation layer 155 (e.g., an end of the intermediate inorganic encapsulation layer 155). In addition, the extension portion TFE3a of the second inorganic encapsulation layer TFE3 may be in contact with the extension portion TFE1a of the first inorganic encapsulation layer TFE1.

Meanwhile, in an embodiment, when the second inorganic encapsulation layer TFE3 and the intermediate inorganic encapsulation layer 155 are made of the same material, the second inorganic encapsulation layer TFE3 and the intermediate inorganic encapsulation layer 155 may be formed integrally with each other without an interface therebetween, as illustrated in FIGS. 15 and 19. In this case, as described above, the second inorganic encapsulation layer TFE3 on the organic encapsulation layer TFE2 may have a greater thickness than a thickness corresponding to the intermediate inorganic encapsulation layer 155.

Meanwhile, in an embodiment, when the second inorganic encapsulation layer TFE3 and the intermediate inorganic encapsulation layer 155 are made of the same material, the second inorganic encapsulation layer TFE3 may be deposited on the substrate SUB in the third chamber described above.

With the method of fabricating the display device, according to an embodiment, an edge portion of the organic layer (for example, an edge portion of the non-display area NDA of the substrate) may be removed using the intermediate inorganic encapsulation layer 155 as the mask. Accordingly, the dams DAM1 and DAM2 for preventing a flow of the organic layer 888 may be omitted. For example, according to an embodiment, a process of forming the dams DAM1 and DAM2 in the dam area DAMA may be omitted. In addition, the edge portion of the organic layer 888 may be removed as described above, and thus, an inclined surface of the organic encapsulation layer TFE2 generated by the flow of the organic layer 888 at an edge of the substrate SUB may not be viewed. Accordingly, a process of forming an additional organic layer (e.g., 130 of FIG. 23) for preventing such an inclined surface of the organic encapsulation layer TFE2 from being viewed may be omitted. Therefore, a fabricating process is simplified, such that a fabricating cost of the display device may be reduced.

According to an embodiment, the dams DAM1 and DAM2 may be omitted, and thus, an edge area of the substrate SUB may be reduced by a portion of the dam area DAMA where the dams DAM1 and DAM2 are omitted. Accordingly, a bezel area of the display device 10 may be reduced. In addition, an inclined surface of an edge portion of the organic encapsulation layer TFE2 is removed at the edge of the substrate SUB, and thus, deterioration of touch sensitivity due to a decrease in thickness of the organic layer at the edge area of the substrate SUB may also be minimized.

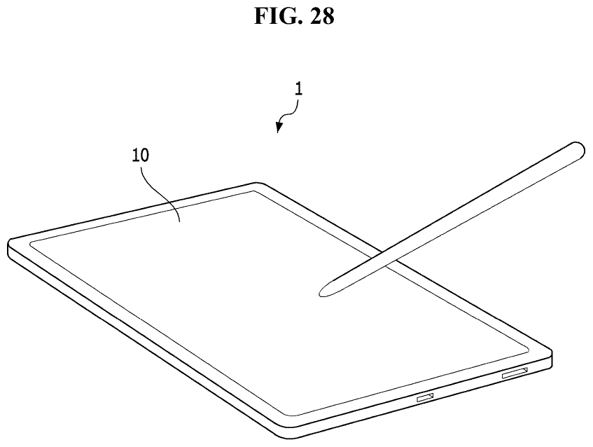

FIG. 28 is a perspective view illustrating an electronic device to which the display device is applied, according to an embodiment.

In an embodiment and referring to FIG. 28, a tablet personal computer (PC) 1 to which the display device 10, according to an embodiment, is applied is illustrated as an example of the electronic device. However, the display device 10, according to an embodiment, may also be applied to other electronic devices in addition to the tablet PC 1. For example, the display device 10, according to an embodiment, may be applied to electronic devices that display moving images or still images. As an example, the display device 10, according to an embodiment, may be applied to portable electronic devices such as mobile phones, smartphones, smart watches, watch phones, mobile communication terminals, electronic notebooks, electronic books, portable multimedia players (PMPs), navigation devices, and ultra mobile PCs (UMPCs). In another embodiment, the display device 10 may be applied as a display screen of various electronic devices such as televisions, laptop computers, monitors, billboards, or the Internet of Things (IOTs).

The display device according to the embodiment can be applied to various electronic devices. The electronic device according to one embodiment includes the display device described above and may further include modules or devices having additional functions in addition to the display device.

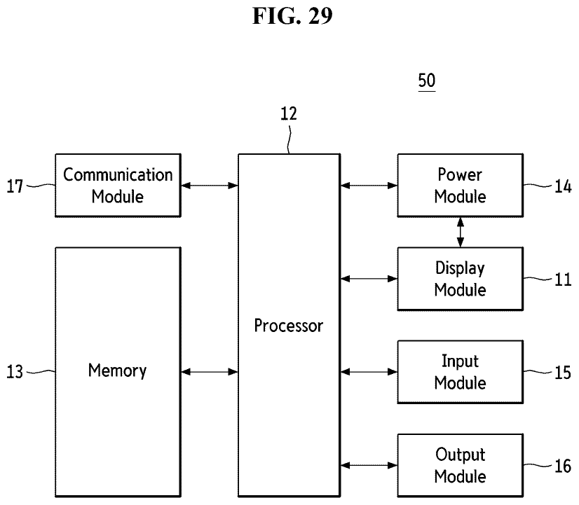

FIG. 29 is a block diagram of an electronic device according to one embodiment. Referring to FIG. 29, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

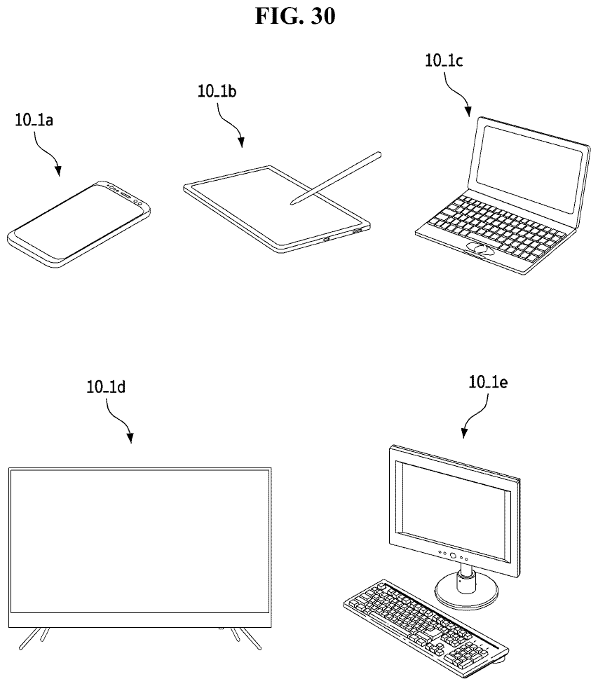

FIGS. 30, 31, and 32 are schematic diagrams of electronic devices according to various embodiments. FIGS. 30 to 32 illustrate examples of various electronic devices to which the display device according to the embodiments is applied.

FIG. 30 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

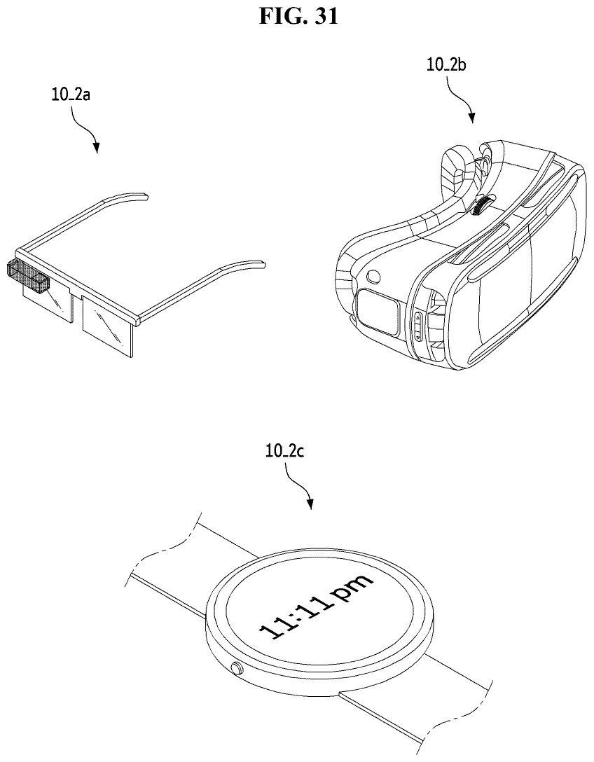

FIG. 31 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

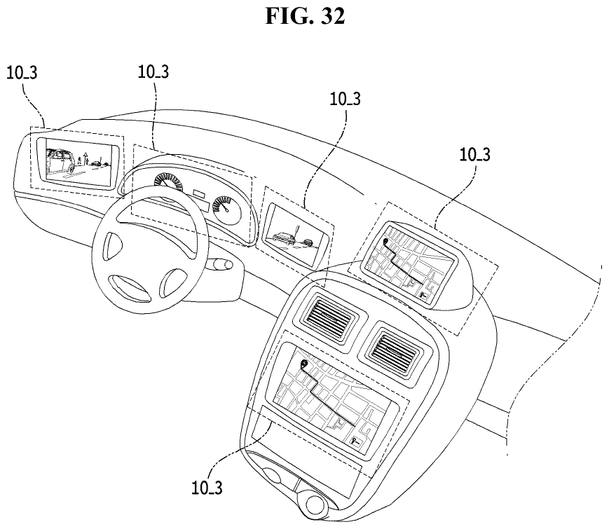

The smart watch 10_2c includes a biometric sensor as an input device, and may provide biometric information recognized by the biometric sensor to the user through the display module. FIG. 32 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be understood by one of ordinary skill in the art to which the invention belongs that the invention may be implemented in other specific forms without changing the technical spirit or essential features of the invention. Therefore, it is to be understood that the embodiments described above are illustrative rather than being restrictive in all aspects. It is to be understood that all modifications and alterations and their equivalents fall within the scope of the invention. Thus, it will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A display device comprising:
a substrate;
a first electrode disposed on the substrate;
a light emitting layer disposed on the first electrode;
a second electrode disposed on the light emitting layer; and
an encapsulation layer disposed on the second electrode,
wherein the encapsulation layer includes:
a first inorganic encapsulation layer disposed on the second electrode;
an organic encapsulation layer disposed on the first inorganic encapsulation layer;
a second inorganic encapsulation layer disposed on the organic encapsulation layer and the first inorganic encapsulation layer; and
an intermediate inorganic encapsulation layer disposed between the organic encapsulation layer and the second inorganic encapsulation layer, wherein
any surfaces of the intermediate inorganic encapsulation layer opposing each other is in contact with the organic encapsulation layer, and wherein an other of the surfaces of the intermediate inorganic encapsulation layer opposing each other is in contact with the second inorganic encapsulation layer.

2. The display device of claim 1, wherein an end of the organic encapsulation layer is disposed in a non-display area between a display area of the substrate and a groove of an edge of the substrate.

3. The display device of claim 1, further comprising a scan driver connected to scan lines disposed in a display area of the substrate and disposed in a non-display area of the substrate,
wherein an end of the organic encapsulation layer is disposed in the non-display area of the substrate between the display area of the substrate and the scan driver.

4. The display device of claim 1, wherein the intermediate inorganic encapsulation layer is surrounded by the organic encapsulation layer and the second inorganic encapsulation layer.

5. The display device of claim 1, wherein the intermediate inorganic encapsulation layer includes a protrusion portion that does not overlap the organic encapsulation layer.

6. The display device of claim 5, wherein the protrusion portion overlaps an extension portion of the second inorganic encapsulation layer.

7. The display device of claim 6, wherein an extension portion of the first inorganic encapsulation layer and the extension portion of the second inorganic encapsulation layer are in contact with each other.

8. The display device of claim 5, wherein the protrusion portion has a length smaller than or equal to about 20 μm.

9. The display device of claim 1, wherein an end of the organic encapsulation layer has an inclined surface.

10. The display device of claim 9, wherein an angle formed by the end of the organic encapsulation layer and a lower surface of the organic encapsulation layer is an acute angle.

11. The display device of claim 10, wherein the angle formed by the end of the organic encapsulation layer and the lower surface of the organic encapsulation layer is greater than or equal to about 20° and smaller than about 90°.

12. The display device of claim 9, wherein an angle formed by the end of the organic encapsulation layer and a lower surface of the organic encapsulation layer is an obtuse angle.

13. The display device of claim 12, wherein the angle formed by the end of the organic encapsulation layer and the lower surface of the organic encapsulation layer is greater than or equal to about 90° and smaller than or equal to about 120°.

14. The display device of claim 1, further comprising at least one dam disposed in a dam area of the substrate.

15. The display device of claim 1, further comprising an organic layer disposed on the second inorganic encapsulation layer.

16. A display device comprising:
a substrate;
a first electrode disposed on the substrate;
a light emitting layer disposed on the first electrode;
a second electrode disposed on the light emitting layer; and
an encapsulation layer disposed on the second electrode,
wherein the encapsulation layer includes:
a first inorganic encapsulation layer disposed on the second electrode;
an organic encapsulation layer disposed on the first inorganic encapsulation layer; and
a second inorganic encapsulation layer disposed on the organic encapsulation layer and the first inorganic encapsulation layer, wherein
the second inorganic encapsulation layer has a greater thickness on the organic encapsulation layer than on the first inorganic encapsulation layer.

17. The display device of claim 16, wherein an end of the organic encapsulation layer is disposed in a non-display area between a display area of the substrate and a groove of an edge of the substrate.

18. The display device of claim 17, further comprising a scan driver connected to scan lines disposed in the display area and disposed in the non-display area of the substrate,
wherein the end of the organic encapsulation layer is disposed in the non-display area between the display area and the scan driver.

19. The display device of claim 16, wherein the second inorganic encapsulation layer includes a protrusion portion that does not overlap the organic encapsulation layer,
wherein the protrusion portion overlaps an extension portion of the second inorganic encapsulation layer.

20. An electronic device comprising a display device providing a screen,
wherein the display device includes:
a substrate;
a first electrode disposed on the substrate;
a light emitting layer disposed on the first electrode;
a second electrode disposed on the light emitting layer; and
an encapsulation layer disposed on the second electrode,
wherein the encapsulation layer includes:
a first inorganic encapsulation layer disposed on the second electrode;
an organic encapsulation layer disposed on the first inorganic encapsulation layer;
a second inorganic encapsulation layer disposed on the organic encapsulation layer and the first inorganic encapsulation layer; and
an intermediate inorganic encapsulation layer disposed between the organic encapsulation layer and the second inorganic encapsulation layer, wherein
any surfaces of the intermediate inorganic encapsulation layer opposing each other is in contact with the organic encapsulation layer, and wherein an other of the surfaces of the intermediate inorganic encapsulation layer opposing each other is in contact with the second inorganic encapsulation layer.
